(19) United States
(12) Patent Application Publication
(10) Pub. No.: US 2005/0122828 A1
(43) Pub. Date: Jun. 9, 2005

(54) MAGNETIC SWITCHING DEVICE AND MEMORY USING THE SAME

(75) Inventors: Akihiro Odagawa, Hirakata-shi (JP); Hiroshi Sato, Tsukuba-shi (JP); Toshikazu Yamada, Tsukuba-shi (JP); Yuji Ishii, Tsukuba-shi (JP); Isao Inoue, Tsukuba-shi (JP); Hiroshi Akoh, Tsukuba-shi (JP); Masashi Kawasaki, Tsukuba-shi (JP); Hidenori Takagi, Tsukuba-shi (JP)

Correspondence Address: MERCHANT & GOULD PC, P.O. BOX 2903, MINNEAPOLIS, MN, 55402-0903, US

(73) Assignees: Matsushita Electric Industrial Co., Ltd., Kadoma-shi (JP); National Institute of Advanced Industrial Science and Technology, Tsukuba-shi (JP)

(21) Appl. No.: 10/953,489

(22) Filed: Sep. 28, 2004

(30) Foreign Application Priority Data
Sep. 29, 2003 (JP) 2003-338250

(51) Int. Cl. G11C 8/02

(52) U.S. Cl. 365/232

(57) ABSTRACT

A magnetic switching device of the present invention includes: at least one transition member; at least one electrode; and at least one free magnetic member. The transition member contains a perovskite compound that contains at least a rare earth element and an alkaline-earth metal, the electrode and the free magnetic member are arranged in parallel and in a noncontact manner on the transition member, at least one of the free magnetic members is coupled magnetically with the transition member, and the transition member undergoes at least ferromagnetism-antiferromagnetism transition by injecting or inducing electrons or holes, whereby a magnetization direction of at least one of the free magnetic members changes. This configuration is applicable to a magnetic memory that records/reads out magnetization information of the free magnetic layer and various magnetic devices that utilize a resistance change of the magnetoresistive effect portion.

### FIELD OF THE INVENTION

The present invention relates to a reproduction head for a magnetic recording device such as a magneto-optical disk, a hard disk, a digital data streamer (DDS) and a digital VTR, which are used for information communication terminals; an angular velocity magnetic sensor for sensing a rotation speed; a stress/acceleration sensor that senses a change in stress or acceleration; and a magnetoresistive sensor typified by a heat sensor or a chemical reaction sensor that utilizes a change in the magnetoresistive effect caused by heat or chemical reaction. The present invention also relates to a magnetic solid-state memory typified by a magnetic random access memory, a reconfigurable memory and the like; and a current switch (magnetic switch) device utilizing magnetism; and a voltage-magnetization switch device that performs magnetization reversal by voltage and the like.

### BACKGROUND OF THE INVENTION

Since a memory utilizing magnetism stores information based on spins of a magnetic substance, a nonvolatile memory can be implemented. Therefore such a memory is considered as one of the devices that are excellent for realizing a power-thrifty and high-speed information terminal in the future. Until now, it has been found that an artificial lattice film, made of magnetic films that are exchange-coupled via a non-magnetic film, shows a giant magnetoresistive effect (GMR) (M. N. Baibich et al., Phys. Rev. Lett., Vol. 61 (1988) 2472.), and a MRAM using a GMR film also has been proposed (K. T. M. Ranmuthu et al., IEEE Trans. on Magn. 29 (1993) 2593.). Although a non-magnetic layer in the afore-mentioned GMR film is a conductive film such as Cu, research has been conducted vigorously for a tunnel type GMR film (TMR) that uses an insulation film such as Al₂O₃ as the non-magnetic layer, and a MRAM using this TMR film also has been proposed. The MRAM using the TMR film is expected to realize a larger output and a higher-density memory than that using the GMR film. Along with this, the possibility of substituting for a high-density memory such as a DRAM also has started to be examined, and it has been expected to establish an architecture in several nanos to several tens of nanometers, which is intended for an ultra-high density memory in the future. For a size domain from several nanos to several tens of nanometers, in which quantal influences on the conduction become intense, a device architecture unlike a conventional one is required. Since the memory utilizing magnetism stores information on spins that are quanta, such a memory is expected as a new device and a circuit that can transmit spin information directly or that can control transmission spins directly.

Furthermore, the magnetized state in a magnetic substance is known to be determined primarily by the sum of exchange energy, crystal magnetic anisotropic energy, magnetostatic energy, and Zeeman energy generated by an external magnetic field. Among them, the physical quantities that can be controlled so as to induce magnetization reversal are the magnetostatic energy and the Zeeman energy. In the case of controlling the magnetized state of a magnetic device with electric energy, a magnetic field generated when a current flows has been used conventionally (JP 2003-92440 A).

However, for example, the energy conversion efficiency for the magnetic field generation with a line current is only about 1%. Furthermore, in the case of the line current, the intensity of a generated magnetic field is inversely proportional to a distance. In many cases, it is necessary to provide an insulator between a lead through which a line current is allowed to flow and a magnetic device that utilizes a magnetic field generated from the lead. Therefore, the energy conversion efficiency is decreased to a level less than 1%. In the case of a magnetic device whose magnetized state should be controlled with electric energy, such a thing is a factor of preventing the widespread use of it in industry.

### SUMMARY OF THE INVENTION

Therefore, in order to cope with the above-stated conventional problems, it is an object of the present invention to provide a magnetic switching device and a memory using the same that can reduce substantially the energy consumption of a general magnetic device whose magnetic state is changed by an external magnetic field, which is enabled by providing a method for reversing the magnetic state in a magnetic substance at a high energy conversion efficiency and providing a preferable configuration example of a device.

A magnetic switching device of the present invention includes: at least one transition member; at least one electrode; and at least one free magnetic member. The transition member includes a perovskite compound that contains at least a rare earth element and an alkaline-earth metal. The electrode and the free magnetic member are arranged in parallel and in a noncontact manner on the transition member. At least one of the free magnetic members is coupled magnetically with the transition member. The transition member undergoes at least ferromagnetism-antiferromagnetism transition by injecting or inducing electrons or holes, whereby a magnetization direction of at least one of the free magnetic members changes.

A random access type memory of the present invention includes: a plurality of voltage switches; a plurality of transition members that undergo magnetic transition by voltages applied by the voltage switches; a plurality of free magnetic members whose magnetization directions are changed by the transition members; and a plurality of magnetoresistive effect portions that read out the magnetization directions of the free magnetic members. Each voltage switch includes a semiconductor switch device that is integrated on a semiconductor substrate. The semiconductor switch device includes at least one transition member, at least one electrode and at least one free magnetic member. The transition member includes a perovskite compound that contains at least a rare earth element and an alkaline-earth metal. The electrode and the free magnetic member are arranged in parallel and in a noncontact manner on the transition member. At least one of the free magnetic members is coupled magnetically with the transition member. The transition member undergoes at least ferromagnetism-antiferromagnetism transition by injecting or inducing electrons or holes, whereby a magnetization direction of at least one of the free magnetic members changes.

### BRIEF DESCRIPTION OF THE DRAWINGS

FIGS. 1A to B schematically show a magnetic switching device of one embodiment of the present invention in cross-section.

FIGS. 2A to B schematically show a magnetic switching device of another embodiment of the present invention in cross-section.

FIGS. 3A to B schematically show a magnetic switching device of still another embodiment of the present invention in cross-section.

FIGS. 4A to B schematically show a magnetic switching device of a further embodiment of the present invention in cross-section.

FIGS. 5A to B schematically show a magnetic switching device of a still further embodiment of the present invention in cross-section.

FIGS. 6A to B schematically show a magnetic switching device of another embodiment of the present invention in cross-section.

FIGS. 7A to B schematically show a magnetic switching device of still another embodiment of the present invention in cross-section.

FIG. 8 schematically shows a magnetic switching device of a further embodiment of the present invention in cross-section.

FIG. 9 schematically shows a magnetic switching device of a still further embodiment of the present invention in cross-section.

FIG. 10 is for explaining an output detection operation of a memory according to one embodiment of the present invention.

FIG. 11 is a schematic wiring diagram including a magnetic switching device of a memory according to one embodiment of the present invention.

FIG. 12 is a schematic wiring diagram including a magnetic switching device of a memory according to one embodiment of the present invention.

FIG. 13 is a schematic wiring diagram including a magnetic switching device of a memory according to one embodiment of the present invention.

FIGS. 14A to B are schematic wiring diagrams, including a magnetic switching device of a memory according to one embodiment of the present invention.

FIGS. 15A to E show planar shape of a free magnetic layer of a magnetic switching device according to one embodiment of the present invention.

FIG. 16 schematically shows a configuration of a reconfigurable memory device according to one embodiment of the present invention, including magnetic switching devices.

FIGS. 17A to B are for explaining the operation of a memory including a magnetic switching device according to one embodiment of the present invention.

FIGS. 18A to B are for explaining the operation of a memory including a magnetic switching device according to one embodiment of the present invention.

FIG. 19 schematically shows a magnetic switching device of one embodiment of the present invention in cross-section.

FIGS. 20A to I schematically show a manufacturing procedure of a magnetic switching device according to one embodiment of the present invention.

FIGS. 21A to F schematically show a manufacturing procedure of a magnetic switching device according to one embodiment of the present invention.

FIGS. 22A to B show a configuration of a magnetic switching device according to one embodiment of the present invention.

FIGS. 23A to B show a configuration of a magnetic switching device according to one embodiment of the present invention.

FIG. 24 shows a configuration of a voltage-controlled magnetic memory device according to one embodiment of the present invention.

### DETAILED DESCRIPTION OF THE INVENTION

A feature of the configuration of the present invention resides in that the transition member includes a perovskite compound that contains at least a rare earth element and an alkaline-earth metal, and the electrode and the free magnetic member are arranged in parallel and in a noncontact manner on the transition member. As the rare earth element, Sc, Y, La, Ce, Pr, Nd, Pm, Sm, Eu, Gd, Tb, Dy, Ho, Er, Tm, Yb, Lu and the like are available, for example. As the alkaline-earth metal, Ca, Sr, Ba, Ra and the like are available, for example. As the perovskite compound, Nd_{0.5}Sr_{0.5}MnO₃, La_{0.8}Sr_{0.2}CoO₃, La_{0.2}Sr_{0.8}RuO₃, La_{0.8}Ca_{0.2}VO₃, Pr_{0.7}Ca_{0.3}MnO₃, La_{0.7}Ca_{0.3}CrO₃, Gd_{0.9}Ba_{0.1}FeO₃, La_{0.9}Sr_{0.1}NiO₃ and the like are available, for example. In the above description, the arrangement of the electrode and the free magnetic member in parallel and in a noncontact manner on the transition member means that the electrode and the free magnetic member are arranged in a noncontact manner. In other words, the electrode and the free magnetic member are arranged to be separated from each other.

Furthermore, at least one transition member, at least one electrode, at least one free magnetic member and at least one magnetization stabilization member may be included. At least one of the free magnetic members and the transition member may be coupled magnetically, and the transition member and the magnetization stabilization member may be coupled magnetically. The magnetization stabilization member may include at least one selected from the group consisting of an antiferromagnetic substance, a laminated ferrimagnetic substance and a high coercive force magnetic substance. The transition member may undergo at least ferromagnetism-antiferromagnetism transition by injecting or inducing electrons or holes, whereby a magnetization direction of the free magnetic member changes.

Furthermore, at least one transition member, at least one electrode, at least one free magnetic member, at least one magnetic member and at least one magnetization stabilization member may be included. The transition member may be arranged between the free magnetic member and the magnetic member so as to be coupled magnetically, and the magnetic member and the magnetization stabilization member may be coupled magnetically. The magnetization stabilization member may include at least one selected from the group consisting of an antiferromagnetic substance, a laminated ferrimagnetic substance and a high coercive force magnetic substance. The transition member may undergo at least ferromagnetism-antiferromagnetism transition by injecting or inducing electrons or holes, whereby a magnetization direction of the free magnetic member changes.

Furthermore, at least one transition member, at least one electrode, at least one free magnetic member, at least one magnetic member and at least one non-magnetic member may be included. The free magnetic member and the transition member may be coupled magnetically. The transition member may undergo at least ferromagnetism-antiferromagnetism transition by injecting or inducing electrons or holes, whereby a magnetization direction of the free magnetic member changes. Between the free magnetic member and the magnetic member that are connected via the non-magnetic member, a resistance may vary in accordance with a change of a magnetization relative angle.

Furthermore, at least one transition member, at least one electrode, at least one free magnetic member, at least one magnetic member, at least one non-magnetic member and at least one magnetic stabilization member may be included. At least one of the free magnetic members and the transition member may be coupled magnetically, and the transition member and the magnetization stabilization member may be coupled magnetically. The magnetization stabilization member may include at least one selected from the group consisting of an antiferromagnetic substance, a laminated ferrimagnetic substance and a high coercive force magnetic substance. The transition member may undergo at least ferromagnetism-antiferromagnetism transition by injecting or inducing electrons or holes, whereby a magnetization direction of the free magnetic member changes. Between the free magnetic member and the magnetic member that are connected via the non-magnetic member, a resistance may vary in accordance with a change of a magnetization relative angle.

Furthermore, at least one transition member, at least one electrode, at least one free magnetic member, at least two magnetic members, at least one non-magnetic member and at least one magnetic stabilization member may be included. The transition member may be arranged between the free magnetic member and one of the magnetic members so as to be coupled magnetically, and another magnetic member and the magnetization stabilization member may be coupled magnetically. The magnetization stabilization member may include at least one selected from the group consisting of an antiferromagnetic substance, a laminated ferrimagnetic substance and a high coercive force magnetic substance. The transition member may undergo at least ferromagnetism-antiferromagnetism transition by injecting or inducing electrons or holes, whereby a magnetization direction of the free magnetic member changes. Between the free magnetic member and the magnetic member that are connected via the non-magnetic member, a resistance may vary in accordance with a change of a magnetization relative angle.

Preferably, the transition member exhibits paramagnetism or non-magnetism when electrons or holes are not injected or induced.

Preferably, the transition member undergoes at least paramagnetism-ferromagnetism transition by injecting or inducing electrons or holes, and by assisting with an external magnetic field during the paramagnetism-ferromagnetism transition, a magnetization direction of the transition layer in a ferromagnetic state changes.

Preferably, the transition member further is opposed to an electrode via at least an insulation member, and by application of a voltage at least between the transition member and the electrode, the transition member undergoes magnetic transition.

In the present invention, preferably, at least one selected from the group consisting of the transition member, the magnetic member, the free magnetic member and the magnetization stabilization member includes a strongly correlated electron material. As the strongly correlated electron material, a perovskite type substance or a perovskite type analogous substance containing at least one element selected from the group consisting of group 3A, group 4A, group 5A, group 6A, group 7A, group 8, group 1B and group 2B are available.

Preferably, the strongly correlated electron material includes RE-ME-O (RE includes at least one type selected from rare-earth metal elements including Y and ME includes at least one type selected from transition metal elements).

Preferably, the strongly correlated electron material includes RE-AE-ME-O (RE includes at least one type selected from rare-earth metal elements including Y, AE includes at least one type selected from alkaline-earth metals and ME includes at least one type selected from transition metal elements).

In the present invention, a magnetic memory can be configured with a plurality of voltage switches; a plurality of transition members that undergo magnetic transition by voltages applied by the voltage switches; a plurality of free magnetic members that are arranged to be coupled magnetically with the transition members, whereby magnetization directions of the free magnetic members are changed by the transition members; and a plurality of magnetoresistive effect portions that read out the magnetization directions of the free magnetic members. Herein, a magnetic random access memory can be configured so that each voltage switch includes a semiconductor switch device that is integrated on a semiconductor substrate.

Furthermore, a reconfigurable memory also can be provided using the configurations of the magnetoresistive device and the magnetic random access memory of the present invention.

According to the present invention, at least one transition layer, at least one electrode and at least one free magnetic layer are included, and at least one of the free magnetic layers is coupled magnetically with the transition layer, and the transition layer undergoes at least magnetic phase change showing ferromagnetism by injecting or inducing electrons or holes, whereby a magnetization direction of the free magnetic layer changes. This configuration is applicable to a magnetic memory that records/reads out magnetization information of the free magnetic layer and various magnetic devices that utilize a resistance change of the magnetoresistive effect portion. Thus, this configuration can enhance the characteristics of a reproduction head of a magnetic recording apparatus used for conventional information communication terminals, such as a magneto-optical disk, a hard disk, a digital data streamer (DDS) and a digital VTR, a cylinder, a magnetic sensor for sensing a rotation speed of a vehicle, a magnetic memory (MRAM), a stress/acceleration sensor that senses a change in stress or acceleration, a thermal sensor, a chemical reaction sensor or the like.

As a material used for the transition layer (i.e., a transition member), a strongly correlated electron material preferably is used as a main component, and a perovskite type substance or a perovskite type analogous substance containing at least one element selected from the group consisting of group 3A, group 4A, group 5A, group 6A, group 7A, group 8, group 1B and group 2B preferably is used as the base material. The substances mentioned herein include Ruddlesden-Popper phase and Auriviellius phase, also.

As the strongly correlated electron material, RE-ME-O (RE includes at least one type selected from rare-earth metal elements including Y and ME includes at least one type selected from transition metal elements) particularly preferably is used. ME preferably includes, for example, at least one type selected from the group consisting of V, Cr, Mn, Fe, Co and Ni. Furthermore, RE-AE-ME-O including AE elements partially, (RE includes at least one type selected from rare-earth metal elements including Y, AE includes at least one type selected from alkaline-earth metal elements and ME includes at least one type selected from transition metal elements) preferably is used.

A preferable material that constitutes the transition layer (i.e., a material that is more preferable for the transition member) is a material that contains a crystal material represented by the general formula of RE₁₋ₓAEₓMEO₃ as the base material. In this formula, x preferably satisfies a range of 0<x≦1. Many substances having 0 and 1 as x are semiconductor layers or insulation layers, so that it is difficult to induce magnetic phase transition by injection of carriers. On the other hand, when x is a specific value that is determined with a type of the ME element and about that value, a strongly correlated effect in which an electron system is governed by spin correlation appears remarkably, so that a phase change of the system appears.

The present invention relates to a switching device using a magnetic phase change due to strong correlation, and depending on a substance of the transition layer, the device shows antiferromagnetism without the application of an electric field and shows ferromagnetism under the application of an electric field. In addition to this, according to the present invention, a device that shows ferromagnetism without the application of an electric field and shows antiferromagnetism under the application of an electric field also can be obtained. Alternatively, a device that shows paramagnetism without the application of an electric field and shows ferromagnetism under the application of an electric field also can be obtained. By using these devices properly, the switching device can be controlled so that the magnetization direction of the free magnetic layer that is coupled magnetically with the transition layer is shifted or a coercive force is increased or decreased.

As a material used for the insulation layer, any material can be used as long as they are insulation layers and semiconductor layers. In particular, a compound of an element selected from the group consisting of: IIa to VIa including Mg, Ti, Zr, Hf, V, Nb, Ta and Cr, lanthanoid including La and Ce, IIb to IVb including Zn, B, Al, Ga and Si and an element selected from the group consisting of F, O, C, N and B, or a polyimide or a phthalocyanine based organic molecular material preferably is used.

As a material preferably used for the electrode, any material having a resistivity of 100 μΩ·cm or smaller can-be used, including Cu, Al, Ag, Au, Pt and TiN.

The magnetization stabilization layer preferably is a multilayer film of a high coercive force magnetic layer, a laminated ferrimagnetic layer and an antiferromagnetic layer or a laminated ferrimagnetic layer and an antiferromagnetic layer. As the high coercive force magnetic layer, a material having a coercive force of 1000 e or higher, including CoPt, FePt, CoCrPt, CoTaPt, FeTaPt, FeCrPt and the like, preferably is used. As the antiferromagnetic layer, PtMn, PtPdMn, FeMn, IrMn, NiMn and the like preferably are used. As the laminated ferrimagnetic layer, a multilayer structure of a magnetic layer and a non-magnetic layer preferably is used, where Co or alloys including Co, such as FeCo, CoFeNi, CoNi, CoZrTa, CoZrB and CoZrNb preferably are used as the magnetic layer and the non-magnetic layer preferably is made of Cu, Ag, Au, Ru, Rh, Ir, Re, Os or alloys and oxides of these metals.

Furthermore, a magnetic semiconductor layer preferably is used, which contains at least one type of element selected from the group consisting of I-V group, I-VI group, II-IV group, II-V group, II-VI group, III-V group, III-VI group, IV-IV group, I-III-VI group, I-V-VI group, II-III-VI group, II-IV-V group and the like, such as ZnO:Mn, ZnS:X, ZnSe:X, ZnTe:X (X=Mn, Fe, Co, Ni), MnAs, JTiO₃:Mn (J=Mg, Ca, Sr, Ba), XF₂, ZnF₂:X (X=Mn, Fe, Co, Ni), CdTe:Mn, CdSe:X, and contains at least one element selected from the group consisting of IVa to VIII and Ib in the compound semiconductor layer so that its magnetism is induced.

Furthermore, as the magnetic layer constituting the free magnetic layer, ferromagnetic layers including a TMA (T denotes at least one type selected from the group consisting of Fe, Co and Ni, M denotes at least one type selected from the group consisting of Mg, Ca, Ti, Zr, Hf, V, Nb, Ta, Cr, Al, Si, Mg, Ge and Ga, and A denotes at least one type selected from the group consisting of N, B, O, F and C) typified by Fe, Co, Ni, FeCo alloy, NiFe alloy, CoNi alloy, NiFeCo alloy, nitrides, oxides, carbides, borides and fluorides magnetic layers such as FeN, FeTiN, FeAlN, FeSiN, FeTaN, FeCoN, FeCoTiN, FeCo(Al,Si)N and FeCoTaN and a TL (T denotes at least one type selected from the group consisting of Fe, Co and Ni, and L denotes at least one type selected from the group consisting of Cu, Ag, Au, Pd, Pt, Rh, Ir, Ru, Os, Ru, Si, Ge, Al, Ga, Cr, Mo, W, V, Nb, Ta, Ti, Zr, Hf, La, Ce, Pr, Nd, Pm, Sm, Eu, Gd, Tb, Dy, Ho, Er, Tm, Yb and Lu) typified by FeCr, FeSiAl, FeSi, FeAl, FeCoSi, FeCoAl, FeCoSiAl, FeCoTi, Fe(Ni)(Co)Pt, Fe(Ni)(Co)Pd, Fe(Ni)(Co)Rh, Fe(Ni)(Co)Ir, Fe(Ni)(Co)Ru, FePt and the like; a half metal material typified by LaSrMnO, LaCaSrMnO and CrO₂; magnetic semiconductor layers typified by QDA (Q denotes at least one type selected from the group consisting of Sc, Y, lanthanoid, Ti, Zr, Hf, Nb, Ta and Zn, A denotes at least one type selected from the group consisting of C, N, O, F, and S, and D denotes at least one type selected from the group consisting of V, Cr, Mn, Fe, Co and Ni) and RDA (R denotes at least one type selected from the group consisting of B, Al, Ga and In, D denotes at least one type selected from the group consisting of V, Cr, Mn, Fe, Co and Ni, and A denotes at least one type selected from the group consisting of As, C, N, O, P and S); a perovskite oxide; a spinel type oxide such as ferrite; and a garnet type oxide are preferably used.

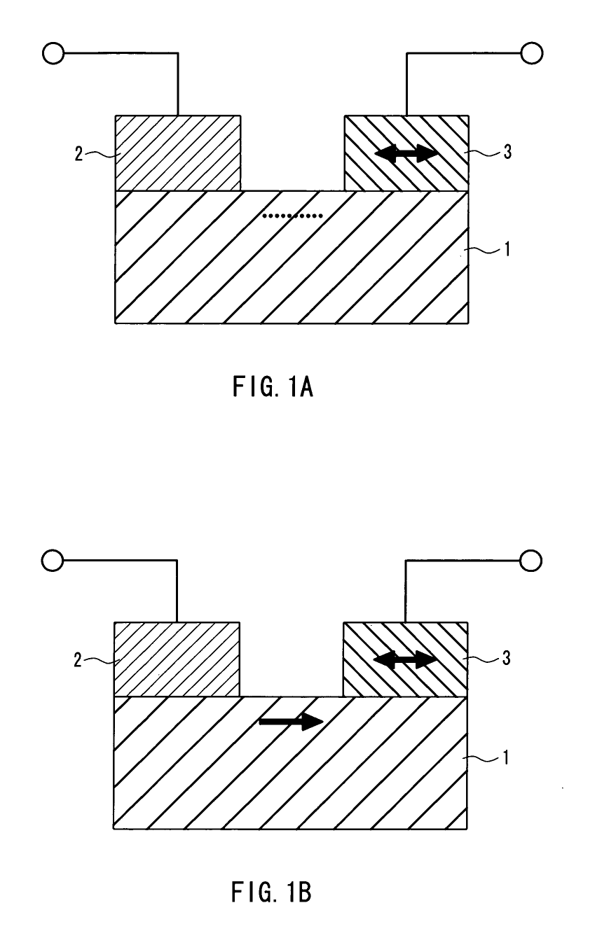

Explanations are given below, with reference to the drawings. FIGS. 1A and 1B show configurations in which an electrode 2 and a free magnetic layer 3 are disposed in a noncontact manner on a transition layer 1. Herein, the free magnetic layer 3 and the transition layer 1 are coupled magnetically, and in accordance with a magnetic phase change of the transition layer 1, the magnetization direction of the free magnetic layer 3 coupled to the transition layer 1 aligns with the magnetization direction of the transition layer 1 that shows ferromagnetism.

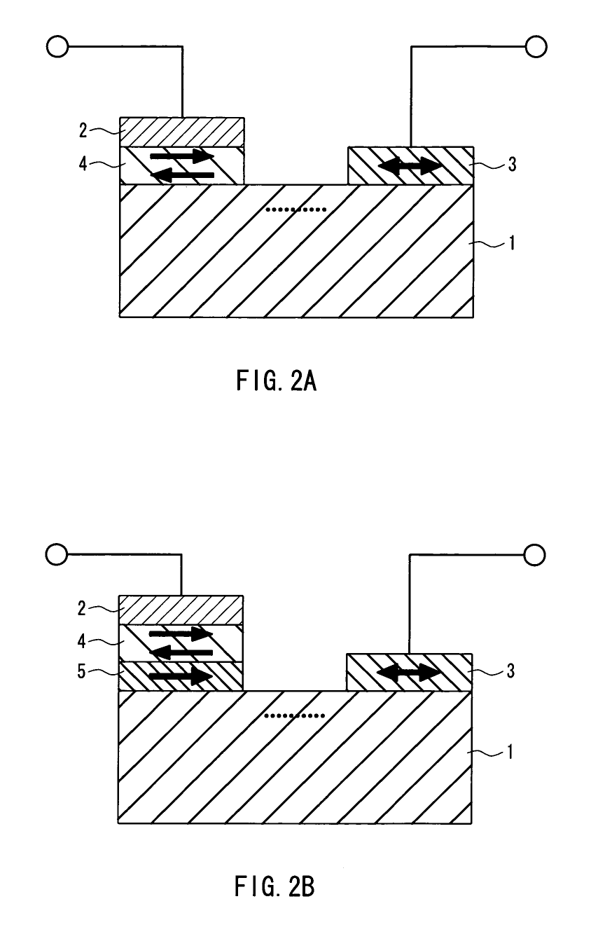

FIG. 2A shows a configuration in which a multilayer member including an electrode 2/an antiferromagnetic layer 4 and a free magnetic layer 3 are disposed in a noncontact manner on a plane via a transition layer 1, and FIG. 2B shows a configuration in which a multilayer member including an electrode 2/an antiferromagnetic layer 4/a ferromagnetic layer 5 and a free magnetic layer 3 are disposed in a noncontact manner on a plane via a transition layer 1. In FIG. 2A, the transition layer 1 is magnetically coupled mutually with the free magnetic layer 3 and the antiferromagnetic layer 4. In FIG. 2B, the transition layer 1 is magnetically coupled mutually with the free magnetic layer 3 and the ferromagnetic layer 5. In both configurations, in accordance with a magnetic phase change of the transition layer 1, the magnetization direction of the free magnetic layer 3 coupled to the transition layer 1 aligns with the magnetization direction of the transition layer 1 that shows ferromagnetism.

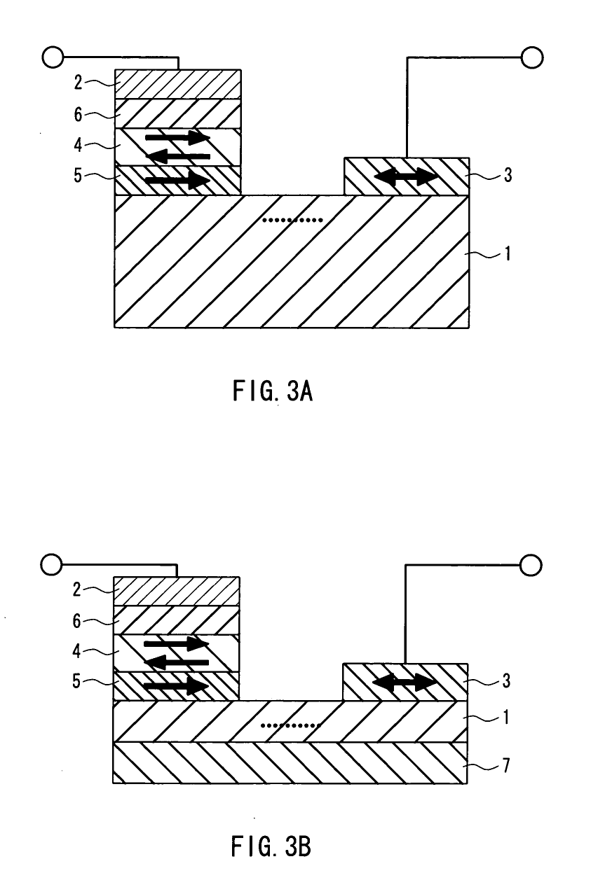

It is preferable that, as shown in FIG. 3A, an insulation layer 6 is provided between an electrode 2 and a transition layer 1 in order to carry out the injection of carriers with efficiency. In this case, a free magnetic layer 3 and an electrode 2/an insulation layer 6; an electrode/an insulation layer/a magnetization stabilization layer; or an electrode 2/an insulation layer 6/an antiferromagnetic layer (magnetization stabilization layer) 4/a ferromagnetic layer 5 may be provided in a plane on the transition layer 1. Furthermore, as shown in FIG. 3B, naturally, it is also preferable that the transition layer 1 is formed as a thin film layer on a base layer 7. As the base layer 7, a perovskite substance is preferable.

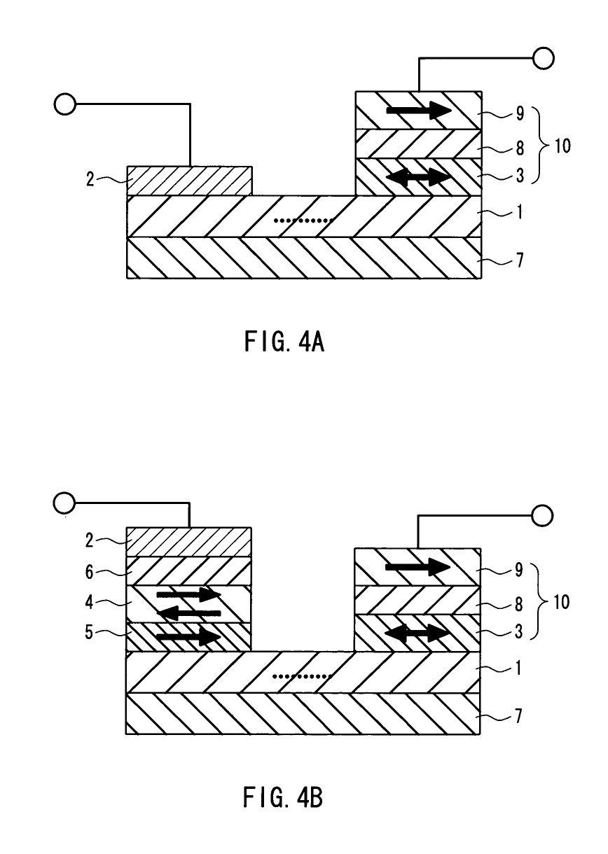

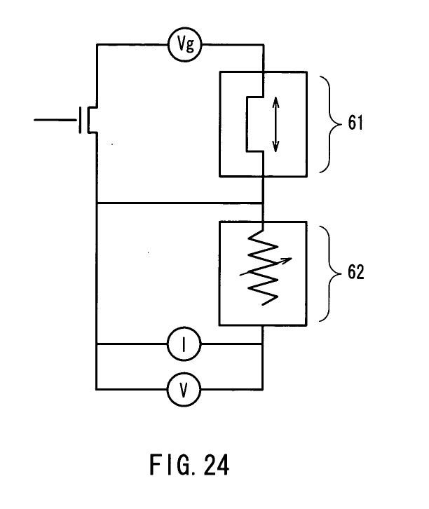

Furthermore, as shown in FIGS. 4A to B, in addition to the configurations shown in FIGS. 1 to 3, a multilayer film 10 that varies in magnetic resistance, which includes a free magnetic layer 3 and is composed of a free magnetic layer 3/a non-magnetic layer 8/a ferromagnetic layer (fixed magnetic layer) 9 may be formed so as to constitute a magnetic switching device. This multilayer film 10 constitutes a magnetoresistive device portion. That is, as shown in FIG. 24, a voltage-controlled magnetic memory device can be configured. In this drawing, reference numeral 61 denotes a magnetic switching device and 62 denotes a magnetoresistive device portion. In such a device, a memory operation of the memory device can be performed by realizing parallel and antiparallel states of the magnetization direction of two ferromagnetic layers via a non-magnetic layer of the magnetoresistive device.

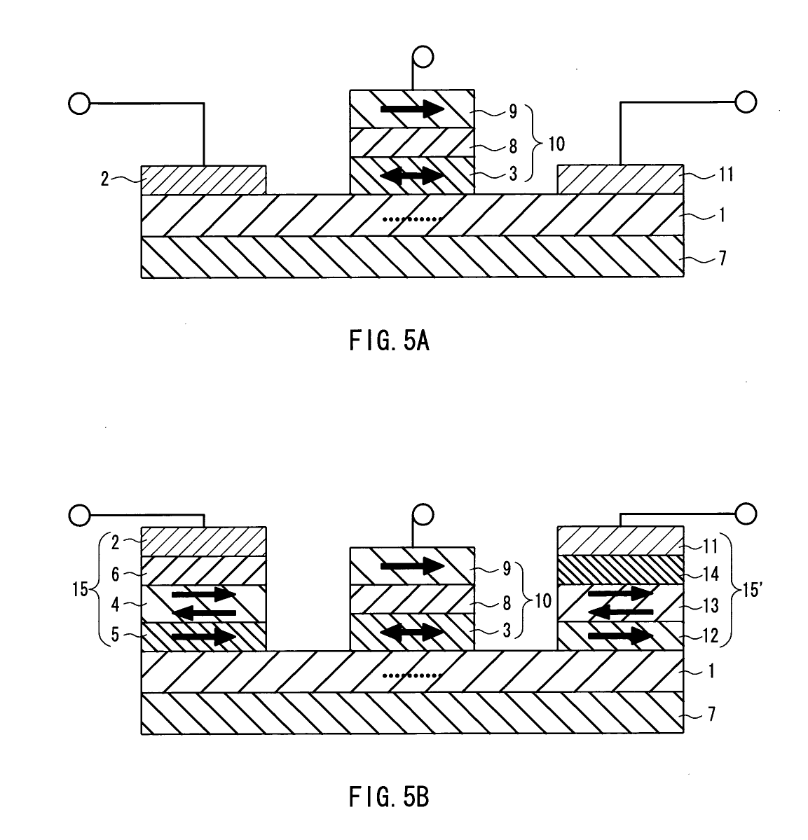

Next, as shown in FIG. 5A, electrodes 2 and 11 are provided on a plane of a transition layer 1, and a multilayer member 10 made up of a free magnetic layer 3/a non-magnetic layer 8/a ferromagnetic layer (fixed magnetic layer) 9 is disposed between the electrodes. A voltage is applied between the electrodes 2 and 11, thus allowing a change in the transition layer 1 so as to change a magnetic resistance of the magnetic multilayer member 10 on the transition layer 1.

As shown in FIG. 5B, a multilayer member 15 made up of a ferromagnetic layer 5, an antiferromagnetic layer 4 and an insulation layer 6 may be formed beneath the electrode 2, and a multilayer member 15′ made up of a ferromagnetic layer 12/an antiferromagnetic layer 13/an insulation layer 14 may be formed beneath the electrode 11.

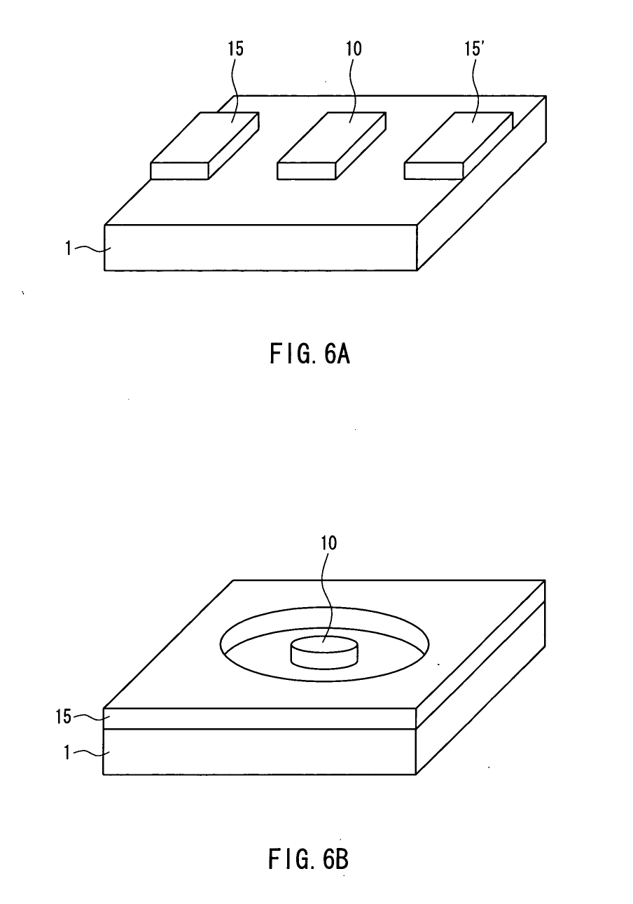

A switching operation using such an in-plane arrangement can be implemented by the characteristics of the magnetic phase change possessed by the transition layer that is capable of spreading to all layers. Conceivably, this results from a distinctive filling control caused by the use of a strongly correlated electron material as the transition layer. From this, although FIGS. 1 to 5 show typical cross-sectional configurations, a desired device can be realized even with in-plane arrangements as in FIGS. 6A to B. FIG. 6A is a perspective view of FIG. 5B. In FIG. 6B, a multilayer body 10 made up of a free magnetic layer 3/a non-magnetic layer 8/a ferromagnetic layer (fixed magnetic layer) 9 is disposed at a center on a transition layer 1, and a multilayer film 15 is formed in a noncontact manner so as to surround the periphery of the multilayer body 10.

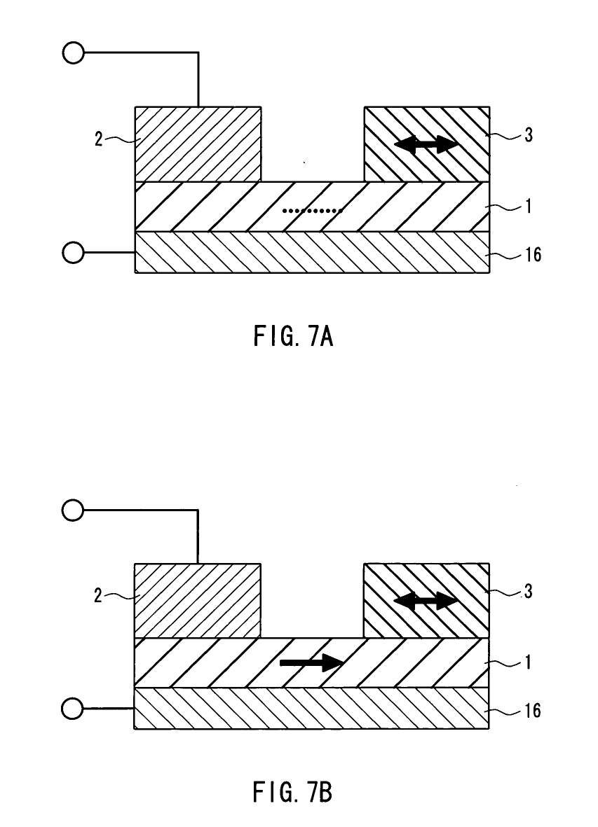

FIG. 7A shows another configuration, which shows the configuration in which an electrode 16 and a transition layer 1 are laminated in this stated order, and an electrode 2 and a free magnetic layer 3 are disposed on the transition layer 1 to be in-plane arranged. As compared with the configurations shown in FIGS. 1 to 6, a voltage can be applied between the electrodes in a lamination direction, and therefore a distance between the electrodes can be decreased in manufacture, thus enabling low-voltage driving. As shown in FIG. 7B, in accordance with a magnetic phase change of the transition layer 1, the magnetization direction of the free magnetic layer 3 coupled to the transition layer 1 aligns with the magnetization direction of the transition layer 1 that shows ferromagnetism.

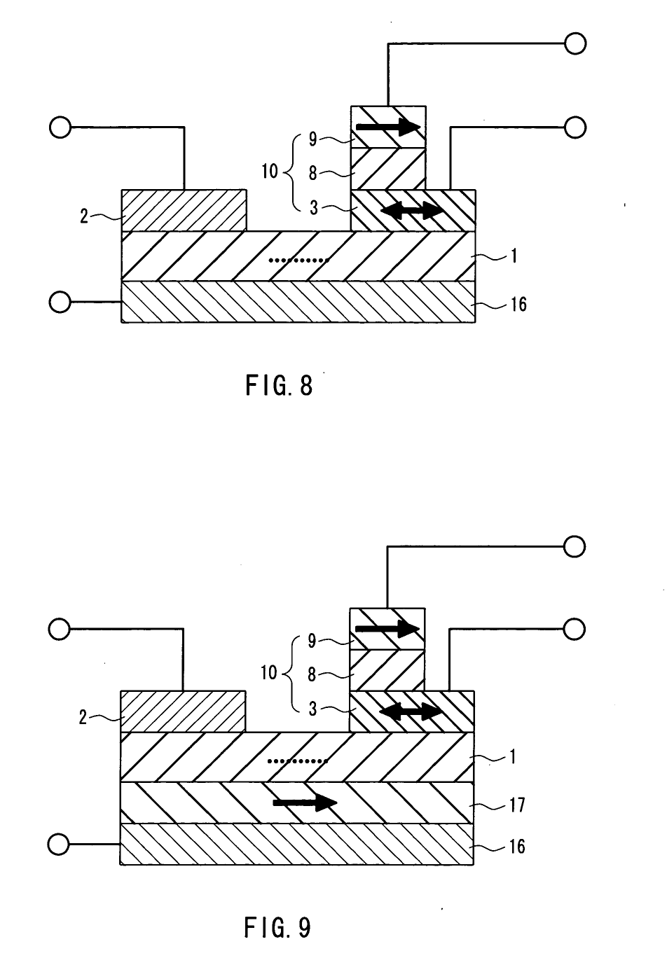

As shown in FIG. 8, a transition layer 1 may be formed on an electrode 16, and a multilayer film 10 that varies in magnetic resistance, made up of a free magnetic layer 3/a non-magnetic layer 8/a ferromagnetic layer (fixed magnetic layer) 9, may be formed thereon so as to constitute a magnetic switching device of the present invention.

As shown in FIG. 9, a ferromagnetic layer 17 may be formed on an electrode 16 and an underlayer as a transition layer 1 may be formed thereon. Then, an electrode 2 and a free magnetic layer 3 may be disposed on the transition layer 1 to be in-plane arranged. In this case, when the magnetic phase of the transition layer 1 is to be changed, the magnetization direction of the transition layer 1 can be controlled by the magnetization of the ferromagnetic layer 17 that is magnetically coupled. In particular, such an in-plane arrangement is favorable because this configuration is effective also for controlling in-plane magnetic domains.

The afore-mentioned configurations of the present invention can be implemented by conventional thin-film processes and micromachining processes. The respective magnetic layers, the antiferromagnetic layers, the interlayer insulation layers and the electrodes and the like can be manufactured by PVD methods including sputtering methods such as pulse laser deposition (PLD), ion beam deposition (IBD), cluster ion beam deposition, RF, DC, ECR, helicon, ICP and an opposed target, MBE, ion plating, or the like, as well as other CVD methods, a plating method, a sol-gel method or the like.

As micromachining, a physical or chemical etching method generally used for a semiconductor process, a GMR head production process and the like, such as ion milling, RIE and FIB may be combined with a photolithography technique using a stepper and an EB method for forming a fine pattern. Furthermore, for planarization of the surface of the electrodes and the like, CMP and cluster-ion beam etching also are used effectively.

The use of magnetic switching devices having the thus described configurations enables the production of a magnetic memory.

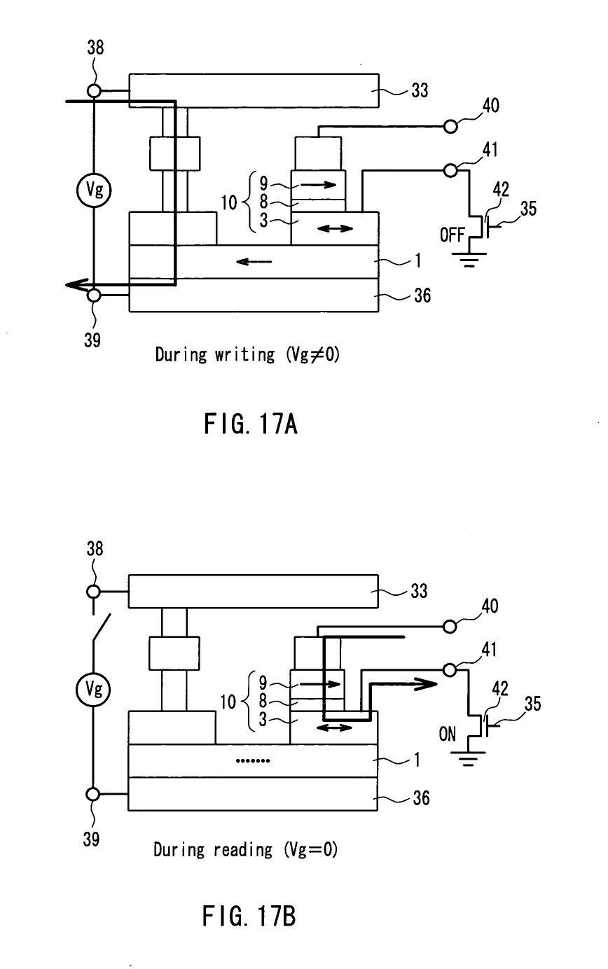

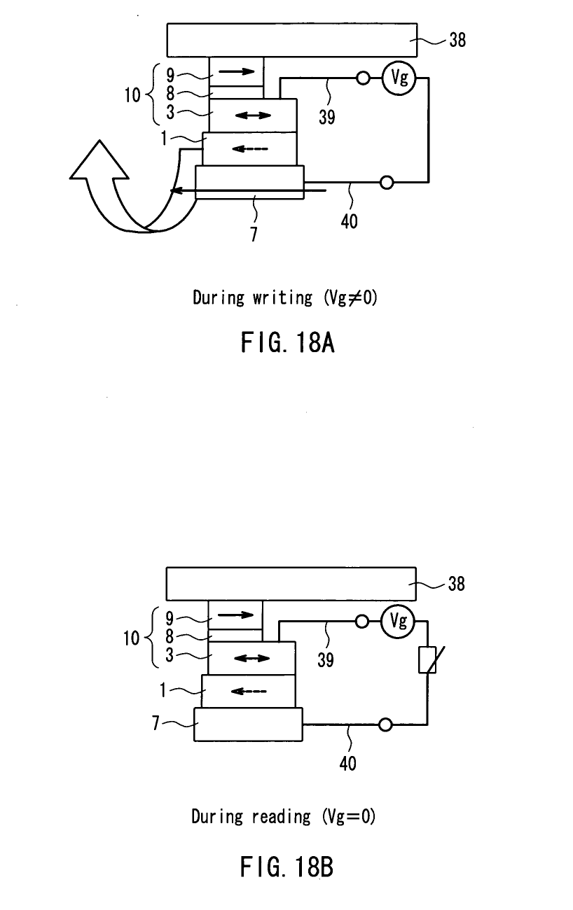

FIGS. 17A to B show one example of the case where memory devices are arranged in a matrix form. FIG. 17A shows the case during writing, where a voltage is applied between a terminal 38 and a terminal 39 so as to induce magnetism of a transition layer 1, thus writing magnetization information on a free magnetic layer 3. The terminal 38 is connected with a word line 1 (33), and the terminal 39 is connected with a word line 2 (36). Herein, preferably, a current is allowed to flow through the word line 1 (33) or the word line 2 (36) concurrently to generate a magnetic field, so as to assist the magnetization rotation.

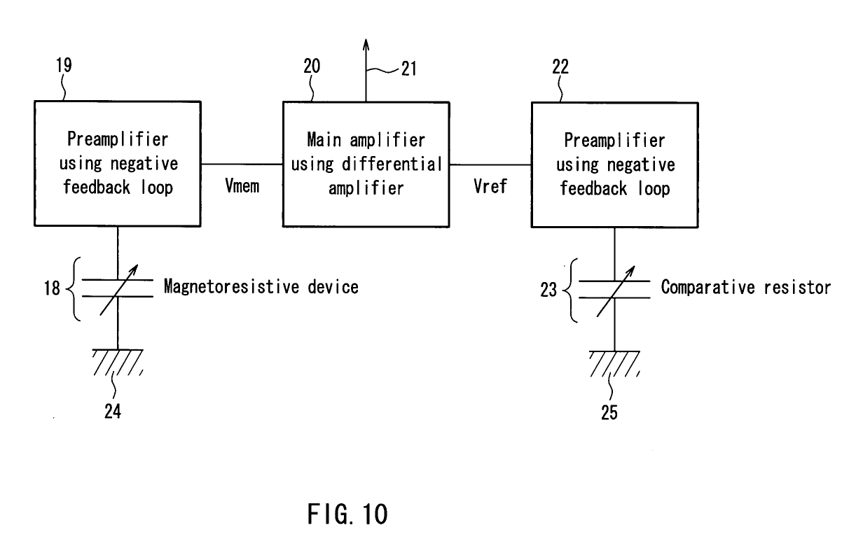

On the other hand, during reading, a field effect transistor (FET) 42 is turned ON as shown in FIG. 17B, and a resistance appearing between a terminal 40 and a terminal 41 is detected. The terminal 40 is connected with a bit line 34, and the terminal 41 is connected with a drain electrode side of the FET 35. The sense line 35 is connected with a gate electrode side of the FET. For the actual detection, differential detection as shown in FIG. 10 preferably is performed, and its difference is detected by determining a difference between a resistance value of a magnetoresistive device 10 (magnetoresistive device 18 in FIG. 10) obtained from a voltage appearing between the terminal 40 and the terminal 41 and a resistance value obtained from a comparative resistor 23. As the comparative resistor, one of the magnetoresistive devices preferably is used. Thereby, the amount corresponding to a change in resistance that is generated due to the magnetic resistance can be detected with efficiency. Furthermore, a difference in output from the comparative resistor including a wiring resistance may be used for canceling the wiring resistance and a reference device resistance of the comparative resistor. This configuration makes it easier to improve a S/N ratio, and therefore is preferable. FIG. 10 shows one example of a general differential amplification for the differential detection, more specifically, a difference between a voltage Vₘₑₘ and a voltage V_{ref}, i.e., a voltage |Vₘₑₘ−V_{ref}|, is obtained as an output 21 by using a main amplifier 20 that is a differential amplifier, where a voltage obtained from a resistance of the magnetoresistive device 18 is amplified by a preamplifier 19 so as to obtain the voltage Vₘₑₘ and a voltage obtained from a resistance of the comparative resistor 23 is amplified by a preamplifier 22 so as to obtain the voltage V_{ref}.

Note here that although FIG. 17 shows the example where a FET is used as a selection device of the memory devices, a rectifying device such as a diode may be used and a similar operation can be carried out.

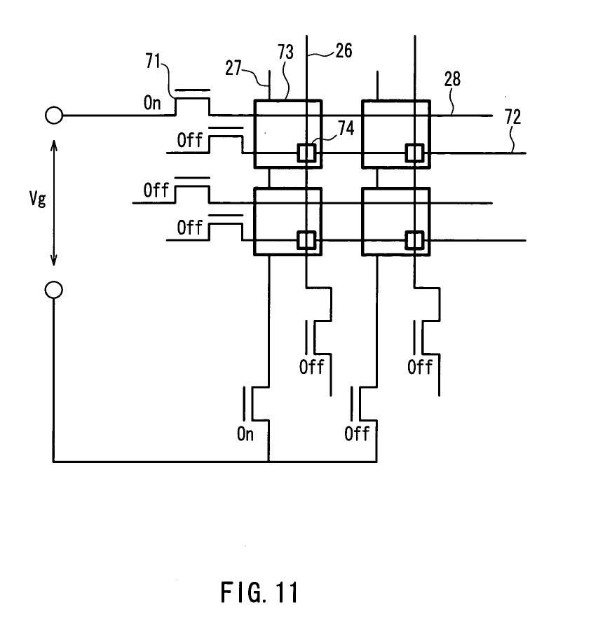

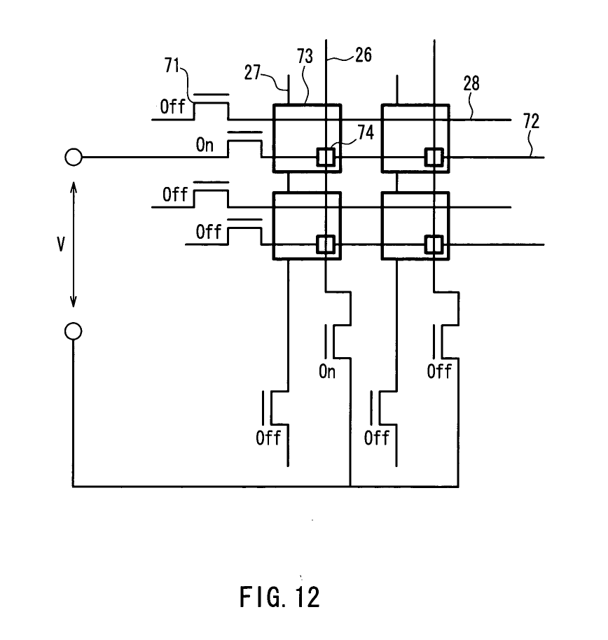

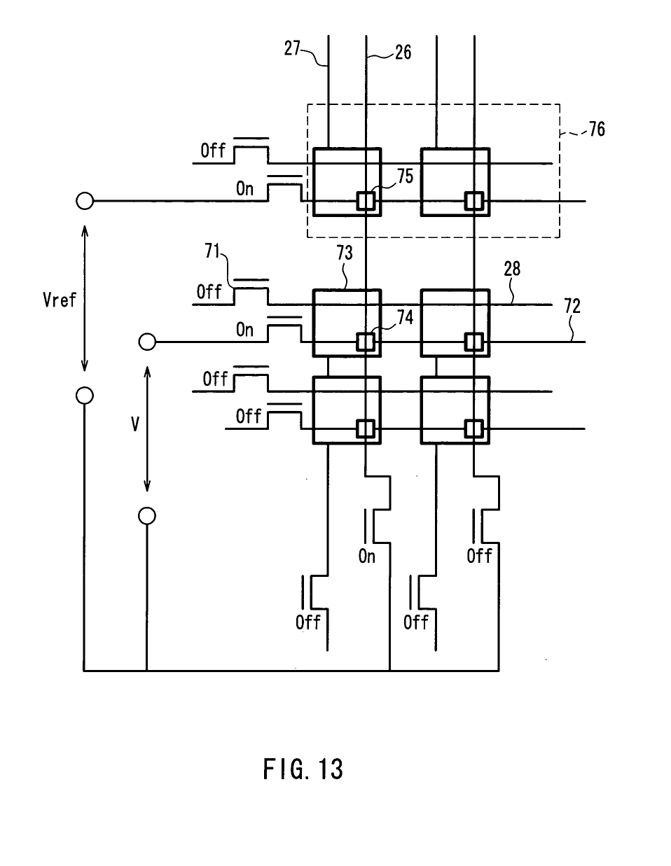

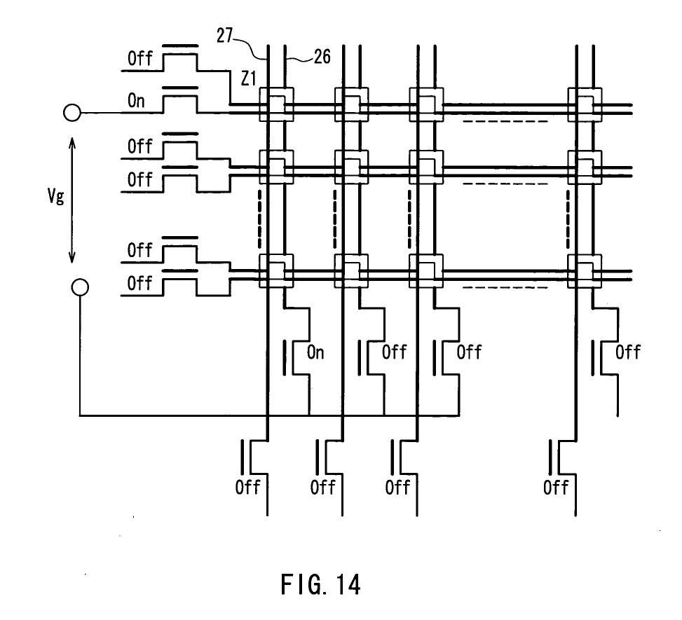

FIGS. 11 and 12 show the state where a magnetic random access memory is configured. Memory devices are configured with a portion 73 corresponding to the magnetic switching device 61 in FIG. 24 and a portion 74 corresponding to the magnetoresistive device portion 62. When memory information is to be written, firstly, a word line 1 (28) and a word line 2 (27) are used to apply a voltage to a transition layer as shown in FIG. 11, and the switching function of the magnetic switching device portion 73 is utilized for performing the writing to the memory, which is a magnetization change in a magnetic layer of the magnetoresistive device portion 74. Each device is selected by switching of pass transistors provided on the periphery. On the other hand, when the contents of the memory are to be read out, as shown in FIG. 12, a resistance (when a constant current is applied, a voltage value V at that time) between a bit line 26 and a sense line 72 is output for the detection. For the detection, as shown in FIG. 13, a difference of a voltage V of a device resistance (magnetoresistive device 74 in FIG. 13) and a voltage V_{ref} of a comparative resistor (comparative resistor 75 in FIG. 13) preferably is differential-detected using the principle of FIG. 10. The comparative resistor may be arranged at each appropriate block of a device array, if required, as in a comparative resistor row (76 in FIG. 13) or a comparative resistor column as shown in FIG. 13, which is preferable because the number of selected pass transistors can be reduced.

### WORKING EXAMPLES

The following describes more specific working examples.

### Working Example 1

Samples were manufactured in the following manner using a pulse laser deposition (PLD) technique and a magnetron sputter method:

Sample 1-1

A laminated body was manufactured so that MgO(100) substrate/NdBa₂Cu₃O₇(300)/Nd_{0.5}Sr_{0.5}MnO₃(100)/Ni_{0.81}Fe_{0.19}(20)/Cu(3)/Co_{0.9}Fe_{0.1}(20) were laminated in this stated order (the unit of numerals in parentheses is nm, which show thicknesses).

The NdBa₂Cu₃O₇ layer and the Nd_{0.5}Sr_{0.5}MnO₃ layer were manufactured by PLD at a substrate temperature of about 600 to 800° C. (typically 750° C.), and each layer of NiFe, Cu and CoFe was manufactured by sputtering at a substrate temperature of a room temperature (27° C.).

During the PLD and the sputtering, the sample was conveyed so as to maintain high vacuum (in-situ transportation).

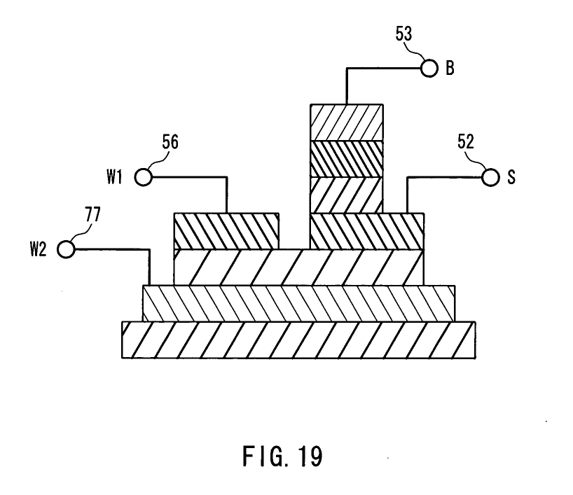

Processing was conducted on the laminated body by an electron beam (EB) technique and a photolithography technique so as to manufacture the configuration as shown in FIG. 19.

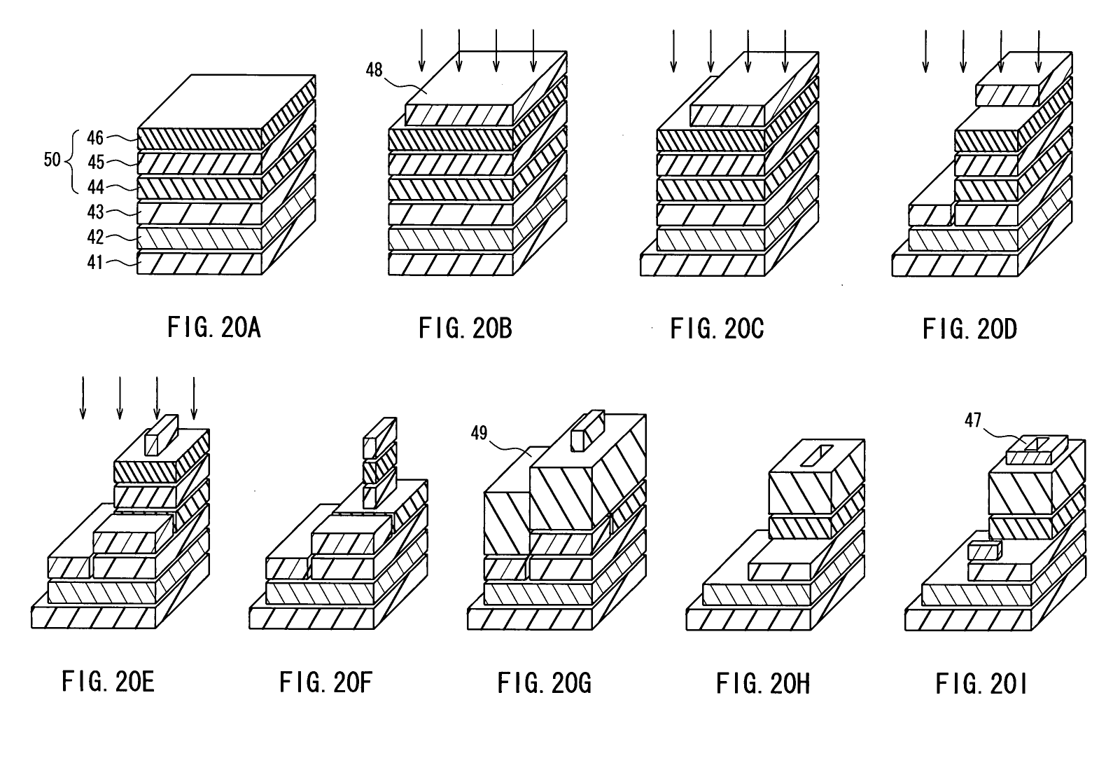

The configuration was manufactured by the process shown in FIGS. 20A to I. Firstly, FIG. 20A shows a state of a manufactured multilayer film, in which a base layer 41, an electrode 42, a transition layer 43, a free magnetic layer 44, a non-magnetic layer 45 and a fixed magnetic layer 46 are laminated in this stated order. At an upper portion of the fixed magnetic layer 46, an antiferromagnetic layer and a cap electrode layer may be included. Herein, the free magnetic layer 44, the non-magnetic layer 45 and the fixed magnetic layer 46 will be a portion for constituting a magnetoresistive device portion 50. First of all, in FIG. 20B, a pattern resist 48 was formed by a photolithography technique so as to determine a layout of a lower electrode, and a pattern for a portion from the electrode 42 to the fixed magnetic layer 46 was formed by a technique such as ion milling to have the same shape as that of the pattern resist. Following this, as shown in FIG. 20C, a pattern resist 48 was formed by the photolithography technique similarly to the above so as to determine a layout of a transition layer, and a pattern for a portion from the transition layer 43 to the fixed magnetic layer 46 was formed by a technique such as ion milling. Next, as shown in FIG. 20D, a pattern resist 48 was formed by the photolithography technique similarly to the above so as to determine a layout of a free magnetic layer, and a pattern for a portion from the free magnetic layer 44 to the fixed magnetic layer 46 was formed by a technique such as ion milling. In FIG. 20E, a pattern for a portion from the non-magnetic layer 45 to the fixed magnetic layer 46 was formed similarly. As a result of the pattern formation by the technique such as ion milling, as shown in FIG. 20F, a mesa structure including the non-magnetic layer 45 to the fixed magnetic layer 46 could be formed. Although not illustrated, the mesa structure may include the free magnetic layer. While the resist remaining during the formation of the mesa structure was left, as shown in FIG. 20G, an interlayer insulation layer 49 was deposited thereon. After a lift-off process, as shown in FIG. 20H, an electrode 47 was deposited, followed by processing of the electrode 47 into a desired pattern by the same technique as above, whereby a device to be evaluated was obtained that had a configuration shown in FIG. 20I. FIG. 20I had the same configuration as that shown in FIG. 19, and connection was conducted assuming that a terminal (B) 53 in FIG. 19 was a bit line, a terminal (S) 52 was a sense line, a terminal (W1) 56 was a word line 1 and a terminal (W2) 77 was a word line 2, and the device was evaluated.

As electrodes for wiring, Au, Ag, Pt, Cu, Al and the like were used. In this working example, an electrode having a multilayer structure such as Ta(5)/Cu(500)/Pt(10) was used with consideration given to a contacting property and the resistance to processing.

Herein, the NdBa₂Cu₃O₇ layer was a conductive oxide and was provided as the electrode, and the Nd_{0.5}Sr_{0.5}MnO₃ layer was provided as the transition layer and the NiFe layer, the Cu layer and the CoFe layer were provided as the free magnetic layer, the non-magnetic layer and the fixed magnetic layer, respectively. Herein, the magnetic multilayer film of Ni_{0.81}Fe_{0.19}/Cu/Co_{0.9}Fe_{0.1} formed a magnetoresistive changing part having a configuration of a CPP type GMR.

The operation of the magnetic switching device configured in this working example was confirmed as follows:

Firstly, as shown in FIG. 19A, a resistance between a B terminal 48 and a S terminal 49 was measured beforehand. Next, a voltage was applied between a S terminal 49 and a W terminal 50, and after the S terminal 49 and the W terminal 50 were disconnected, the resistance between the B terminal 48 and the S terminal 49 was measured again, whereby the operation of the switching device of the present invention was evaluated. When a voltage 0.1 V≦V≦20 V was applied between the electrode 42 and the free magnetic layer 44, about 10% of difference in resistance could be detected between the B-S terminals, which showed the formation of a desired device. Herein, a temperature range for the measurement was from 4 K to 370 K, and a phenomenon at about 200 K or lower was confirmed.

From the afore-mentioned magnetic resistance characteristics using the B-S terminals, it was shown that the magnetoresistive effect could be detected naturally by the application of an external magnetic field also, and the device of the present invention was a magnetoresistive changing type switching device.

From this, the basic operation of the switching device having magnetic properties capable of magnetization reversal without the use of an external magnetic field could be confirmed.

Conceivably, in order to obtain such desired characteristics of the present invention, it is important to have a favorable crystallographic consistency between the electrode and the transition layer. Since a perovskite type (including analogous substances) oxide was used for both, the desired characteristics were realized by a favorable compatibility between them.

In the configuration shown in FIG. 19, NiO, MnAs, PtMn or the like, having antiferromagnetism, was deposited on the CoFe magnetic layer. In this configuration, the magnetic resistance characteristics between the B-S terminals showed those distinctive for a spin valve type, and it is expected that the CoFe magnetic layer was coupled magnetically with the antiferromagnetic layer and the magnetization direction was fixed. In other words, according to this configuration of the present invention, a device could be realized such that magnetization information in a free magnetic layer contacting with a transition layer could be controlled by the application of a voltage.

In addition to Sample 1-1, Sample 1-2 was manufactured including MgO(100)substrate/NdBa₂Cu₃O₇(300)/Nd_{0.6}Sr_{0.4}MnO₃(50)/Nd_{0.5}Sr_{0.5}MnO₃(50)/Ni_{0.81}Fe_{0.19}(20)/Cu(3)/Co_{0.9}Fe_{0.1}(5)/Ru(0.9)/Co0.9Fe0.1(5)/IrMn(15)(the unit of numerals in parentheses is nm, which show thicknesses), which were substrate/electrode/antiferromagnetic layer/transition layer/free magnetic layer/non-magnetic layer/fixed magnetic layer. The sample was annealed in the magnetic field at 5 kOe and 280° C. for the alignment of magnetization direction of IrMn. Herein, Co_{0.9}Fe_{0.1}(5)/Ru(0.9)/Co_{0.9}Fe_{0.1}(5)/IrMn(15) formed a fixed magnetic layer having a synthetic ferri type antiferromagnetism coupling structure.

The evaluations similar to Sample 1-1 were conducted to Sample 1-2 also, and an operation as a magnetic switching device was confirmed also in this configuration.

Furthermore, Sample 1-3 was manufactured including MgO(100) substrate/NdBa₂Cu₃O₇(300)/Nd_{0.6}Sr_{0.4}MnO₃(50)/Nd_{0.4}Sr_{0.6}MnO₃(50)/Nd_{0.5}Sr_{0.5}MnO₃(50)/Ni_{0.81}Fe_{0.19}(20)/Co_{0.5}Fe_{0.5}(1)/Al₂O₃(1.2)/Co_{0.5}Fe_{0.5}(5)/Ru(0.9)/Co_{0.5}Fe_{0.5}(5)/IrMn(15) (the unit of numerals in parentheses is nm, which show thicknesses), which were substrate/electrode/antiferromagnetic layer/ferromagnetic layer/transition layer/free magnetic layer/non-magnetic layer/fixed magnetic layer. The sample was annealed in the magnetic field at 5 kOe and 280° C. for the alignment of magnetization direction of IrMn.

Herein, Ni_{0.81}Fe_{0.19}(20)/Co_{0.5}Fe_{0.5}(1) was the free magnetic layer and Co_{0.5}Fe_{0.5}(5)/Ru(0.9)/Co_{0.5}Fe_{0.5}(5)/IrMn(15) formed the fixed magnetic layer. The Al₂O₃ layer was the insulative non-magnetic layer, and Ni_{0.81}Fe₁₉/Co_{0.5}Fe_{0.5}/Al₂O₃/Co_{0.5}Fe_{0.5}/Ru/Co_{0.5}Fe_{0.5}/IrMn constituted a tunnel type magnetoresistive changing portion.

Al₂O₃ as the non-magnetic insulation layer was manufactured by forming an Al film, which was subjected to oxidation, followed by post-oxidation process and was manufactured by sputtering of Al₂O₃. In the post-oxidation process, oxidation was conducted by natural oxidation in a vacuum chamber, by natural oxidation by the application of heat in a vacuum chamber, and by oxidation in plasma in a vacuum chamber. Any process of these could realize a favorable non-magnetic insulation film that functioned as a tunnel barrier. Note here that multi-stages of Al film formation, natural oxidation, Al film formation and natural oxidation may be conducted during the post-oxidation process, and it was found that such a process improved the uniformity of the oxidation film, as well as enabling the reduction of a oxidation time.

The evaluations similar to Sample 1-1 were conducted. A change in resistance was 30% or higher before and after the application of a voltage to the transition layer, and an operation as a magnetic switching device was confirmed in this configuration also.

In this working example, NdBa₂Cu₃O₇ was used as the electrode, which was a conductive oxide layer. In addition to this, REBa₂Cu₃O₇ (Y, La, Pr, Nd, Pm, Sm, Eu, Gd, Tb, Dy, Ho, Er, Tm and Yb were used as RE) could be used, which showed a favorable compatibility with the transition layer and the substrate.

Furthermore, in this working example, MgO was used as the substrate. However, other oxide substrates such as LaAlO₃, NdGaO₃, SrTiO₃, LaSrAlTaO₄ and the like could be used and the device could be embodied. The use of such a substrate allows strongly correlated electron materials constituting the transition layer, the electrode, the antiferromagnetic layer and the ferromagnetic layer to be produced as monocrystals, and therefore is preferable.

Herein, a configuration in which Si/SiO₂ (thermal oxidation) is used as the substrate and Si/SiO₂/Pt(electrode)/(Nd, Sr)MnO₃(transition layer)/NiFe(free magnetic layer)/Al₂O₃ (non-magnetic layer)/(CoFe/IrMn)(fixed magnetic layer) is included also enables the embodiment of the device, although the transition layer is a polycrystal layer, and the magnetic switching operation of the present invention can be realized.

In addition to this, a desired device can be realized also by adopting a perovskite oxide (RE, Sr, Ca)MnO₃ (Y, La, Pr, Nd, Pm, Sm, Eu, Gd, Tb, Dy, Ho, Er, Tm and Yb were used as RE) as the transition layer.

### Working Example 2

Samples were manufactured in the following manner using a pulse laser deposition (PLD) technique and a magnetron sputter method:

A laminated body was manufactured as Sample 2-1 so as to include SrTiO₃(100)substrate/NdBa₂Cu₃O₇(300)/SrTiO₃(50)/Nd_{0.6}Sr_{0.4}MnO₃(50)/Nd_{0.4}Sr_{0.6}MnO₃(50)/Nd_{0.5}Sr_{0.5}MnO₃(50)/Ni_{0.81}Fe_{0.19}(20)/Co_{0.5}Fe_{0.5}(1)/Al₂O₃(1.2)/Co_{0.5}Fe_{0.5}(5)/Ru(0.9)/Co_{0.5}Fe_{0.5}(5)/IrMn(15) that were laminated in this stated order (the unit of numerals in parentheses is nm, which show thicknesses).

The NdBaCuO layer and the respective NdSrMnO layers were manufactured by PLD at a substrate temperature of about 600 to 800° C., and each layer of NiFe, Cu, CoFe, Ru and IrMn was manufactured by sputtering at a substrate temperature of a room temperature (27° C.).

During the PLD and the sputtering, the sample was conveyed so as to maintain high vacuum (in-situ transportation).

Processing was conducted on the laminated body by an electron beam (EB) technique and a photolithography technique, which were in conformance with FIG. 20, to manufacture the configuration as shown in FIG. 19. Herein, the NdBa₂Cu₃O₇ layer was a conductive oxide and was provided as an electrode, the SrTiO₃ layer was provided as an insulation layer, the Nd_{0.6}Sr_{0.4}MnO₃ layer was provided as an antiferromagnetic layer, the Nd_{0.4}Sr_{0.6}MnO₃ layer was provided as a ferromagnetic layer, the Nd_{0.5}Sr_{0.5}MnO₃ layer was provided as a transition layer, the Ni_{0.81}Fe_{0.19}(20)/Co_{0.5}Fe_{0.5}(1) layer was provided as a free magnetic layer, the Al₂O₃ layer was provided as a non-magnetic layer, and the Co_{0.5}Fe_{0.5}(5)/Ru(0.9)/Co_{0.5}Fe_{0.5}(5)/IrMn(15) layer was provided a fixed magnetic layer. Herein, the magnetic multilayer film of Ni_{0.81}Fe_{0.19}(20)/Co_{0.5}Fe_{0.5}(1)/Al₂O₃(1.2)/Co_{0.5}Fe_{0.5}(5)/Ru(0.9)/Co_{0.5}Fe_{0.5}(5)/IrMn(15) formed a magnetoresistive changing part having a TMR type configuration.

Al₂O₃ as the non-magnetic insulation layer was manufactured by forming an Al film, which was subjected to oxidation, followed by post-oxidation processing. During this step, multi-stages of A (0.4 nm) film formation, natural oxidation, Al (0.3 nm) film formation, natural oxidation, Al (0.3 nm) film formation and natural oxidation was conducted. Al₂O₃ after the oxidation had a film thickness of 1.5 nm.

The operation of the magnetic switching device configured in this working example was confirmed as follows:

Firstly, as shown in FIG. 19, a resistance between B-S terminals was measured beforehand. Next, a voltage was applied between S-W terminals, and after the S-W terminals were disconnected, the resistance between the B-S terminals was measured again, whereby the operation of the switching device of the present invention was evaluated. When a voltage 0.1 V≦V≦20 V was applied between the S-W terminals, about 40% of difference in resistance could be detected between the B-S terminals, which showed the formation of a desired device.

In this connection, it can be considered that the charge injection from the electrode to the transition layer via the insulation layer caused magnetic phase transition of the transition layer. Since the magnetic resistance change could be obtained with a sufficient gain, it was found that the configuration via the insulation layer of this working example was favorable.

From the afore-mentioned magnetic resistance characteristics using the B-S terminals, it was shown that the magnetoresistive effect could be detected naturally by the application of an external magnetic field also, and the device of the present invention was a magnetoresistive changing type switching device.

From this, the basic operation of the switching device having magnetic properties capable of magnetization reversal without the use of an external magnetic field could be confirmed.

In addition to Sample 2-1, Sample 2-2 was manufactured including NdGaO₃(100)substrate/La_{0.7}Sr_{0.3}MnO₃(200)/SrTiO₃(50)/Nd_{0.6}Sr_{0.4}MnO₃(50)/Sm0_{0.5}MnO₃(50)/Ni_{0.81}Fe_{0.19}(20)/Co_{0.5}Fe_{0.5}(1)/Al₂O₃(1.2)/Co_{0.5}Fe_{0.5}(5)/Ru(0.9)/Co_{0.5}Fe_{0.5}(5)/PtMn(15) (the unit of numerals in parentheses is nm, which show thicknesses), which were substrate/electrode/insulation layer/antiferromagnetic layer/transition layer/free magnetic layer/non-magnetic layer/fixed magnetic layer. The sample was annealed in the magnetic field at 5 kOe and 280° C. for the alignment of magnetization direction of PtMn. Herein, Co_{0.9}Fe_{0.1}(5)/Ru(0.9)/Co_{0.9}Fe_{0.1}(5)/PtMn(15) formed a fixed magnetic layer having a synthetic ferri type antiferromagnetism coupling structure.

The evaluations similar to Sample 2-1 were conducted to Sample 2-2 also, and an operation as a magnetic switching device was confirmed also in this configuration.

Furthermore, Sample 2-3 was manufactured including LaSrAlTaO₄(100)substrate/La_{0.7}Sr_{0.3}MnO₃(200)/SrTiO₃(50)/Nd_{0.6}Sr_{0.4}MnO₃(50)/Sm_{0.5}Sr_{0.5}MnO₃(50)/Ni_{0.81}Fe_{0.19}(20)/Co_{0.5}Fe_{0.5}(1)/Al₂O₃(1.2)/Co_{0.5}Fe_{0.5}(5)/Ru(0.9)/Co_{0.5}Fe_{0.5}(5)/IrMn(15/) (the unit of numerals in parentheses is nm, which show thicknesses), which were substrate/electrode/antiferromagnetic layer/ferromagnetic layer/transition layer/free magnetic layer/non-magnetic layer/fixed magnetic layer. The sample was annealed in the magnetic field at 5 kOe and 280° C. for the alignment of magnetization direction of IrMn.

Herein, Ni_{0.81}Fe_{0.19}(20)/Co_{0.5}Fe_{0.5}(1) was the free magnetic layer and Co_{0.5}Fe_{0.5}(5)/Ru(0.9)/Co_{0.5}Fe_{0.5}(5)/IrMn(15) formed the fixed magnetic layer. The Al₂O₃ layer was the insulative non-magnetic layer, and Ni_{0.81}Fe_{0.19}/Co_{0.5}Fe_{0.5}/Al₂O₃/Co_{0.5}Fe_{0.5}/Ru/Co_{0.5}Fe_{0.5}/IrMn constituted a tunnel type magnetoresistive changing portion.

In Sample 2-2 and Sample 2-3, La_{0.7}Sr_{0.3}MnO₃ was used as the electrode, which was a conductive oxide layer. In addition to this, (Sr₁₋ₓCaₓ)_{1-y}La_{y}RuO₃ (where 0≦x≦1, 0≦y≦0.9) and Sr₁₋ₓLaₓTi_{1-y}ME_{y}O₃ (where 0≦x≦0.9, 0≦y≦1, ME=V, Nb, Ta, Cr, Mn, Fe, Co, Ni, Cu, Re or Ru) could be used, which showed a favorable compatibility with the transition layer and the substrate.

Furthermore, in this working example, MgO was used as the substrate. However, other oxide substrates such as LaAlO₃, NdGaO₃, SrTiO₃, (La, Sr)₂(Al, Ta)O₃ and the like could be used and the device could be embodied. The use of such a substrate allows strongly correlated electron materials constituting the transition layer, the electrode, the antiferromagnetic layer and the ferromagnetic layer to be produced as monocrystals, and therefore is preferable.

Herein, a configuration in which Si/SiO₂ (thermal oxidation) is used as the substrate and Si/SiO₂/Pt (electrode)/(Nd, Sr)MnO₃(transition layer)/NiFe(free magnetic layer)/Al₂O₃(non-magnetic layer)/(CoFe/IrMn) (fixed magnetic layer) is included also enables the embodiment of the device, although the transition layer is a polycrystal layer, and the magnetic switching operation of the present invention can be realized.

Furthermore, another configuration in which a Si substrate is used and Si substrate/TiN (underlayer)/Pt (electrode)/(Nd, Sr)MnO₃ (transition layer)/NiFe (free magnetic layer)/Al₃O₃(non-magnetic layer)/(CoFe/IrMn) (fixed magnetic layer) is included also can realize the magnetic switching operation of the present invention.

Moreover, still another configuration in which MgO(100) is used as a substrate and MgO substrate/Pt (electrode)/(Nd, Sr)MnO₃(transition layer)/NiFe (free magnetic layer)/Al₂O₃(non-magnetic layer)/(CoFe/IrMn) (fixed magnetic layer) is included also can realize the magnetic switching operation of the present invention, although the transition layer is a polycrystal layer.

In addition to this, a desired device can be realized also by adopting a perovskite oxide (RE, Sr, Ca)MnO₃ (Y, La, Pr, Nd, Pm, Sm, Eu, Gd, Tb, Dy, Ho, Er, Tm and Yb were used as RE) as the transition layer.

### Working Example 3

Samples were manufactured in the following manner using a magnetron sputter method:

A laminated body was manufactured as Sample 3-1 so as to include MgO(100)substrate/Pt(500) SrTiO₃(50)/Nd_{0.6}Sr_{0.4}MnO₃(50)/Nd_{0.4}Sr_{0.6}MnO₃(50)/Nd_{0.5}Sr_{0.5}MnO₃(50)/La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15) that were laminated in this stated order (the unit of numerals in parentheses is nm, which show thicknesses).

Each layer of the SrTiO₃ layer, the NdSrMnO₃ layer and the LaSrMnO₃ layer was manufactured at a substrate temperature of about 600 to 850° C., and each layer of Pt, NiFe, Cu, CoFe, Ru and IrMn was manufactured by sputtering at a substrate temperature of a room temperature (27° C.). Herein, Pt as a lower electrode was heated by a high-temperature film formation step that was conducted downstream. The film formation was conducted in an in-situ manner.

Processing was conducted to the laminated body by an electron beam (EB) technique and a photolithography technique, which were in conformance with FIGS. 20A-I, to manufacture the configuration as shown in FIG. 19. Herein, the Pt layer was provided as an electrode, the SrTiO₃ layer was provided as an insulation layer, the Nd_{0.6}Sr_{0.4}MnO₃ layer was provided as an antiferromagnetic layer, the Nd_{0.4}Sr_{0.6}MnO₃ layer was provided as a ferromagnetic layer, the Nd_{0.5}Sr_{0.5}MnO₃ layer was provided as a transition layer, the La_{0.7}Sr_{0.3}MnO₃(1.2)/Ni_{0.81}Fe_{0.19}(20)/Co_{0.5}Fe_{0.5}(1) layer was provided as a free magnetic layer, the Al₂O₃ layer was provided as a non-magnetic layer, and the Co_{0.5}Fe_{0.5}(5)/Ru(0.9)/Co_{0.5}Fe_{0.5}(5)/IrMn(15) layer was provided a fixed magnetic layer.

Herein, the magnetic multilayer film of Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15) formed a magnetoresistive changing part having a TMR type configuration.

Al₂O₃ as the non-magnetic insulation layer was manufactured by forming an Al film, which was subjected to oxidation, followed by post-oxidation process. During this step, multi-stages of Al (0.4 nm) film formation, natural oxidation, Al (0.3 nm) film formation, natural oxidation, Al (0.3 nm) film formation and natural oxidation was conducted. Al₂O₃ after the oxidation had a film thickness of 1.5 nm.

The operation of the magnetic switching device configured in this working example was confirmed as follows:

Firstly, as shown in FIG. 19A, a resistance between B-S terminals was measured beforehand. Next, a voltage was applied between S-W terminals, and after the S-W terminals were disconnected, the resistance between the B-S terminals was measured again, whereby the operation of the switching device of the present invention was evaluated. When a voltage 0.1 V≦V≦20 V was applied between the S-W terminals, about 40% of difference in resistance could be detected between the B-S terminals, which showed the formation of a desired device.

In this connection, it can be considered that the charge injection from the electrode to the transition layer via the insulation layer caused magnetic phase transition of the transition layer. Since the magnetic resistance change could be obtained with a sufficient gain, it was found that the configuration via the insulation layer of this working example was favorable.

From the afore-mentioned magnetic resistance characteristics using the B-S terminals, it was shown that the magnetoresistive effect could be detected naturally by the application of an external magnetic field also, and the device of the present invention was a magnetoresistive changing type switching device.

From this, the basic operation of the switching device having magnetic properties capable of magnetization reversal without the use of an external magnetic field could be confirmed.

Next, a laminated body was manufactured as Sample 3-2 so as to include NdGaO₃(100)substrate/La_{0.7}Sr_{0.3}MnO₃(100)/LaAlO₃(1.5)/SrTiO₃(50)/LaAlO₃(1.5)/Nd_{0.6}Sr_{0.4}MnO₃(30)/Nd_{0.4}Sr_{0.6}MnO₃(25)/PrBaMn₂O₆(50)/La_{0.7}Ba_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15) that were laminated in this stated order (the unit of numerals in parentheses is nm, which show thicknesses).

The SrTiO₃ layer and the LaAlO₃ layer and the respective layers of the NdSrMnO layer, the LaSrMnO layer, the PrBaMnO layer and the LaBaMnO layer were manufactured at a substrate temperature of about 600 to 850° C., and each layer of Pt, NiFe, Cu, CoFe, Ru and IrMn was manufactured by sputtering at a substrate temperature of a room temperature (27° C.). The film formation and the conveyance between the respective film formation steps were conducted in an in-situ manner.

Processing was conducted to the laminated body by an electron beam (EB) technique and a photolithography technique, which were in conformance with FIGS. 20A-I, to manufacture the configuration in conformance with FIG. 19. Herein, the LaSrMnO layer was provided as an electrode, the LaAlO₃/SrTiO₃/LaAlO₃ layer was provided as an insulation layer, the Nd_{0.6}Sr_{0.4}MnO₃ layer was provided as an antiferromagnetic layer, the Nd_{30.4}Sr_{0.6}MnO₃ layer was provided as a ferromagnetic layer, the PrBaMnO layer was provided as a transition layer, the La_{0.7}Ba_{0.3}MnO₃/Ni_{0.81}Fe_{0.19}/Co_{0.5}Fe_{0.5} layer was provided as a free magnetic layer, the Al₂O₃ layer was provided as a non-magnetic layer, and the Co_{0.5}Fe_{0.5}/Ru/Co_{0.5}Fe_{0.5}/IrMn layer was provided a fixed magnetic layer.

Herein, the magnetic multilayer film of Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15) formed a magnetoresistive changing part having a TMR type configuration.

Al₂O₃ as the non-magnetic insulation layer was manufactured by forming an Al film, which was subjected to oxidation, followed by post-oxidation processing. During this step, multi-stages of Al (0.4 nm) film formation, natural oxidation, Al (0.3 nm) film formation, natural oxidation, Al (0.3 nm) film formation and natural oxidation was conducted. Al₂O₃ after the oxidation had a film thickness of 1.5 nm.

When a voltage 0.1 V≦V≦20 V was applied between the S-W terminals, about 30% of difference in resistance could be detected between the B-S terminals, which showed the formation of a desired device.

### Working Example 4

Samples were manufactured in the following manner using a pulse laser deposition (PLD) technique and a magnetron sputter method:

A laminated body was manufactured as Sample 4-1, where a NdGaO₃(100) substrate was used and NdGaO₃substrate/Nd_{0.5}Sr_{0.5}MnO₃(100)/La_{0.7}Sr_{0.3}MnO₃ (1.5) were laminated in this stated order (the unit of numerals in parentheses is nm, which show thicknesses).

The Nd_{0.5}Sr_{0.5}MnO₃ layer and the La_{0.7}Sr_{0.3}MnO₃ layer were manufactured by PLD at a substrate temperature of about 750 to 900° C.

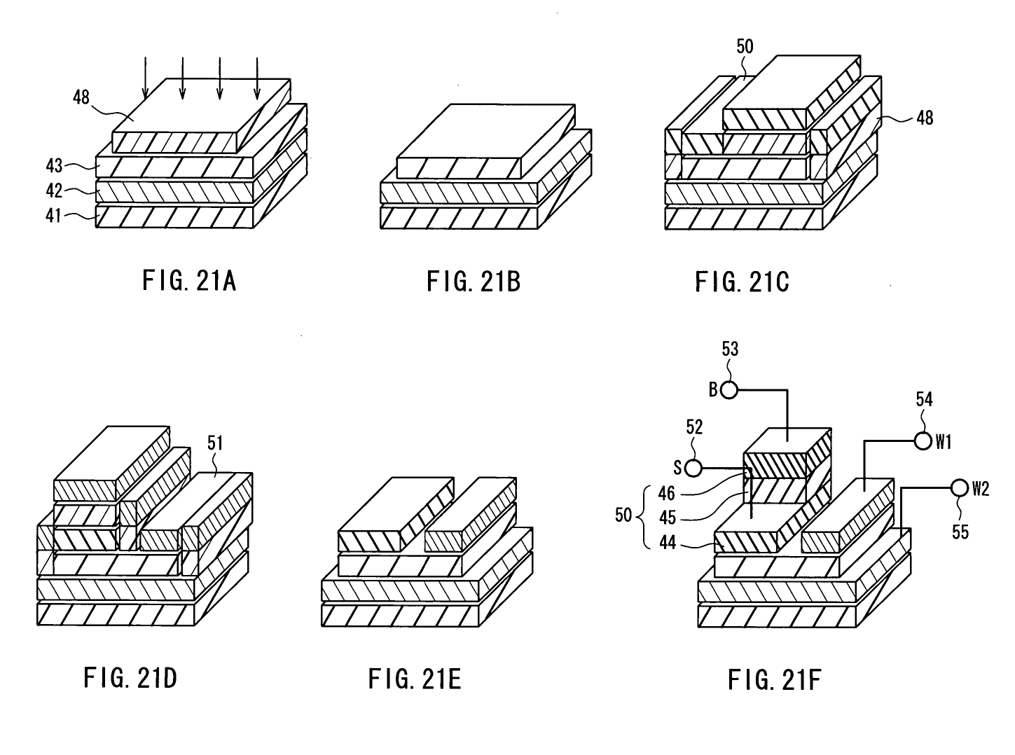

Processing was conducted to the laminated body by an electron beam (EB) technique and a photolithography technique and a device was manufactured by the procedure as shown in FIGS. 21A to F. In FIG. 21A, a base layer 41, an electrode 42 and a transition layer 43 were formed in this stated order.

Thereafter, the transition layer 43 was processed in FIG. 21B, and a magnetic multilayer film portion 50 was formed using a lift-off process in FIG. 21C. The magnetic multilayer film used was composed of Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15), which was formed by sputtering at a substrate temperature of a room temperature (27° C.). In this step, reverse-sputtering was conducted before the deposition for the purpose of removing adhering substances on the transition layer. Along with this, the La_{0.7}Sr_{0.3}MnO₃ (1.5) layer was etched at a portion that was not covered with a resist.

In FIG. 21D, an electrode portion 51 was formed, and in FIGS. 21E to 21F, the magnetic multilayer film portion 50 including free magnetic layer 44/non-magnetic layer 45/fixed magnetic layer 46 was processed, and then terminals 52 to 55 were attached thereto, so as to form a magnetoresistive changing portion.

As electrodes for wiring, Au, Ag, Pt, Cu, Al and the like were used. In this working example, an electrode having a multilayer structure such as Ta(5)/Cu(500)/Pt(10) was used with consideration given to a contacting property and the resistance to processing. In this step, reverse-sputtering was conducted before the deposition for the purpose of surface-etching of the La_{0.7}Sr_{0.3}MnO₃(10) layer.

Herein, the Nd_{0.5}Sr_{0.5}MnO₃ layer was provided as the transition layer, the La_{0.7}Sr_{0.3}MnO₃(10 reverse-sputtered)/Ni_{0.81}Fe_{0.19}(20)/Co_{0.5}Fe_{0.5}(1) layer was provided as the free magnetic layer, the Al₂O₃ layer was provided as the non-magnetic layer and the Co_{0.5}Fe_{0.5}(5)/Ru(0.9)/Co_{0.5}Fe_{0.5}(5)/IrMn(15) layer was provided as the fixed magnetic layer.

Al₂O₃ as the non-magnetic insulation layer was manufactured by forming an Al film, which was then subjected to multi-stage oxidation processing.

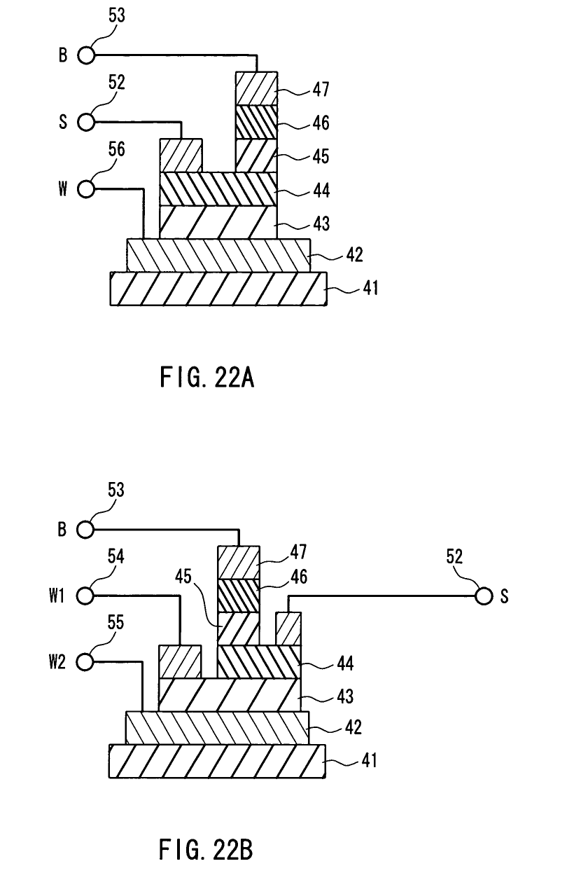

The thus manufactured device typically had a configuration of FIG. 22B. However, a configuration of FIG. 22A also was manufactured depending on the arrangement of the free magnetic layer so as to evaluate the same.

The operation of the magnetic switching device configured in this working example was confirmed as follows:

Firstly, as shown in FIG. 22B, a resistance between B-S terminals was measured beforehand. Next, a voltage was applied between W1-W2 terminals, and after the W1-W2 terminals were disconnected, the resistance between the B-S terminals was measured again, whereby the operation of the switching device of the present invention was evaluated. When a voltage 0.1 V≦V≦20 V was applied between the W terminals, about 10% of difference in resistance could be detected between the B-S terminals, which showed the formation of a desired device. Herein, a temperature range for the measurement was from 4 K to 370 K, and a phenomenon at about 200 K or lower was confirmed.

From the afore-mentioned magnetic resistance characteristics using the B-S terminals, it was shown that the magnetoresistive effect could be detected naturally by the application of an external magnetic field also, and the device of the present invention was a magnetoresistive changing type switching device.

From this, the basic operation of the switching device having magnetic properties capable of magnetization reversal without the use of an external magnetic field could be confirmed.

In addition to Sample 4-1, a laminated body was manufactured as Sample 4-2 including NdGaO₃ substrate/PrBaMn₂O₆(100)/La_{0.7}Sr_{0.3}MnO₃(1.5) (the unit of numerals in parentheses is nm, which show thicknesses).

The PrBaMn₂O₆ layer and the La_{0.7}Sr_{0.3}MnO₃ layer were formed by PLD at a substrate temperature of about 750 to 900° C.

Processing was conducted on the laminated body by an electron beam (EB) technique and a photolithography technique and a device was manufactured by the process as shown in FIG. 21.

The transition layer was processed in FIG. 21B, and a magnetic multilayer film portion was formed using a lift-off process in FIG. 21C. The magnetic multilayer film used was composed of Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15), which was formed by sputtering at a substrate temperature of a room temperature. In this step, reverse-sputtering was conducted before the deposition for the purpose of removing adhering substances on the transition layer. Along with this, the La_{0.7}Sr_{0.3}MnO₃(1.5) layer was etched at a portion that was not covered with a resist.

In FIG. 21D, an electrode portion was formed, and in FIGS. 21E to 21F, the magnetic multilayer film portion was separately processed so as to form a magnetoresistive changing portion.

As electrodes for wiring, Au, Ag, Pt, Cu, Al and the like were used. In this working example, an electrode having a multilayer structure such as Ta(5)/Cu(500)/Pt(10) was used with consideration given to a contacting property and the resistance to processing. In this step, reverse-sputtering was conducted before the deposition for the purpose of surface-etching of the La_{0.7}Sr_{0.3}MnO₃ (10) layer.

Herein, the PrBaMn₂O₆ layer was the transition layer having an A-site ordered perovskite structure, and the La_{0.7}Sr_{0.3}MnO₃ (1.5-reverse-sputtered)/Ni_{0.81}Fe_{0.19}(20)/Co_{0.5}Fe_{0.5}(1) layer was provided as the free magnetic layer, the Al₂O₃ layer was provided as the non-magnetic layer and the Co_{0.5}Fe_{0.5}(9)/Ru(0.9)/Co_{0.5}Fe_{0.5}(9)/IrMn(15) layer was provided as the fixed magnetic layer.

Al₂O₃ as the non-magnetic insulation layer was manufactured by forming an Al film, which was then subjected to multi-stage oxidation processing.

When a voltage 0.1 V≦V≦20 V was applied between W1-W2 terminals, about 40% of difference in resistance could be detected between B-S terminals at a room temperature, which showed the formation of a desired device.

From the afore-mentioned magnetic resistance characteristics using the B-S terminals, it was shown that the magnetoresistive effect could be detected naturally by the application of an external magnetic field also, and the device of the present invention was a magnetoresistive changing type switching device.

From this, the basic operation of the switching device having magnetic properties capable of magnetization reversal without the use of an external magnetic field could be confirmed.

Although PrBaMn₂O₆ was used as the transition layer in this example, when a substance represented by RE₁AE₁ME₂O₆ (RE is a rare earth element, e.g., La, Sm and Gd; AE is an alkaline-earth metal element, e.g., Ba; ME is a transition metal element, e.g., Mn and Co) was used, similar results could be obtained.

Furthermore, in this working example, MgO was used as the substrate. However, other oxide substrates such as LaAlO₃, NdGaO₃, SrTiO₃, LaSrAlTaO₄ and the like could be used and the device could be embodied. The use of such a substrate allows strongly correlated electron materials constituting the transition layer, the electrode, the antiferromagnetic layer and the ferromagnetic layer to be produced as monocrystals, and therefore is preferable.

Furthermore, a configuration in which Si/SiO₂ (thermal oxidation) is used as the substrate and Si/SiO₂/Pt (electrode)/(Nd, Sr)MnO₃ (transition layer)/NiFe (free magnetic layer)/Al₂O₃ (non-magnetic layer)/(CoFe/IrMn) (fixed magnetic layer) is included also enables the embodiment of the device, although the transition layer is a polycrystal layer, and the magnetic switching operation of the present invention as shown in FIG. 22B can be realized.

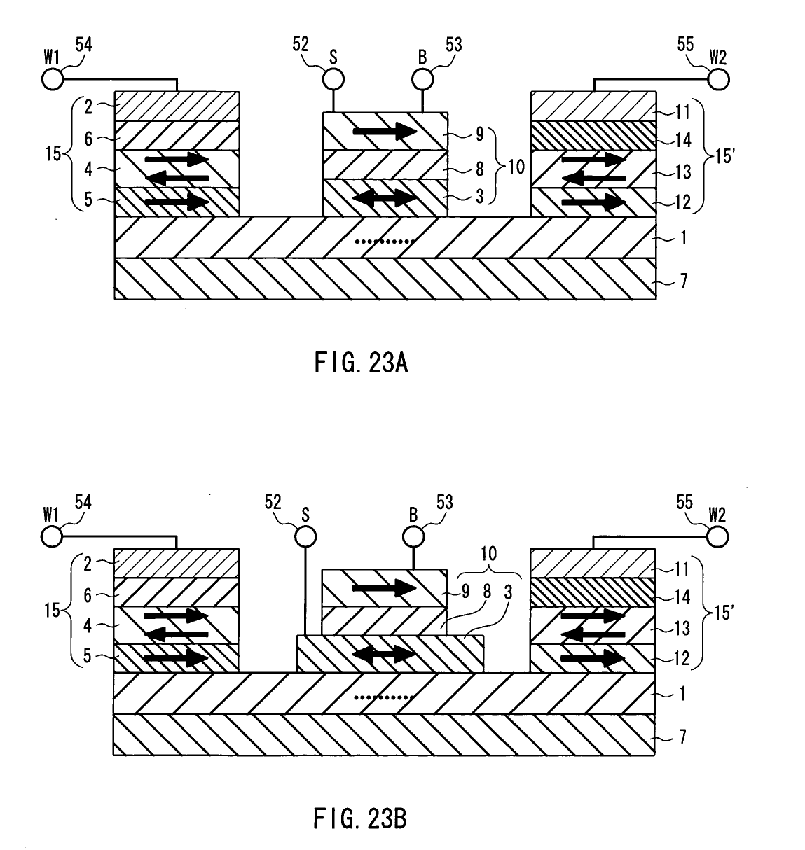

Next, a configuration of FIG. 23B was implemented as Sample 4-4. A NdGaO₃(100) substrate was used as a substrate 7, a PrBaMn₂O₆(100) layer was used as a transition layer 1, a La_{0.7}Sr_{0.3}MnO₃(5) layer was used as ferromagnetic layers 5 and 12, a Nd_{0.6}Sr_{0.4}MnO₃(50) layer was used as antiferromagnetic layers 4 and 13, a SrTiO₃(50) layer was used as insulation layers 6 and 14, a Ta(10)/Cu(500)/Pt(50) layer was used as electrodes 2 and 11, a Ni_{0.81}Fe_{0.19}(20)/Co_{0.5}Fe_{0.5}(1) layer was used as a free magnetic layer 3, an Al₂O₃(2) layer was used as a non-magnetic layer 8, and a Co_{0.5}Fe_{0.5}(9)/Ru(0.9)/Co_{0.5}Fe_{0.5}(9)/IrMn(15) layer was used as a fixed magnetic layer 9. In addition, a Ta(10)/Cu(500)/Pt(50) layer was used as leading electrodes for wirings 52 to 55. The unit of numerals in parentheses is nm, which show thicknesses.

The PrBaMn₂O₆ layer and the La_{0.7}Sr_{0.3}MnO₃ layer were formed by PLD at a substrate temperature of about 750 to 900° C.

The other layers were deposited by sputtering at a room temperature (27° C.). Processing was conducted to the laminated body by EB (electron beam) processing and a photolithography technique, so as to form a device.

The operation of the magnetic switching device configured in this working example was confirmed as follows: firstly, a resistance between B-S terminals was measured beforehand. Next, a voltage was applied between W1-W2 terminals, and after the W1-W2 terminals were disconnected, the resistance between the B-S terminals was measured again, whereby the operation of the switching device of the present invention was evaluated. When a voltage 0.1 V≦V≦20 V was applied between the electrode and the free magnetic layer, about 20% of difference in resistance could be detected between the B-S terminals at a room temperature, which showed the formation of a desired device.

From the afore-mentioned magnetic resistance characteristics using the B-S terminals, it was shown that the magnetoresistive effect could be detected naturally by the application of an external magnetic field also, and the device of the present invention was a magnetoresistive changing type switching device.

From this, the basic operation of the switching device having magnetic properties capable of magnetization reversal without the use of an external magnetic field could be confirmed.

Although the magnetoresistive changing portion in this example had a TMR device structure, in the case of a GMR structure, the operation of the device could be confirmed with the configuration of FIG. 23A.

In addition to this, a desired device can be realized also by adopting a perovskite oxide (RE, Sr, Ca)MnO₃ (Y, La, Pr, Nd, Pm, Sm, Eu, Gd, Tb, Dy, Ho, Er, Tm and Yb were used as RE) as the transition layer.

### Working Example 5

Samples were manufactured in the following manner using a pulse laser deposition (PLD) technique and a magnetron sputter method.

The following laminated bodies of Sample 5-1 to 5-7 were formed. The unit of numerals in parentheses is nm, which show thicknesses.

Sample 5-1:

NdGaO₃(100) substrate/La_{0.7}Sr_{0.3}MnO₃(80)/LaAlO₃(1.5)/SrTiO₃(50)/LaAlO₃(1.5)/Nd_{0.6}Sr_{0.4}MnO₃(30)/Nd_{0.4}Sr_{0.6}MnO₃(25)/La_{0.8}Sr_{0.2}CoO₃(50)/La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15)

Sample 5-2:

NdGaO₃(100) substrate/La_{0.7}Sr_{0.3}MnO₃(80)/LaAlO₃(1.5)/SrTiO₃(50)/LaAlO₃(1.5)/Nd_{0.6}Sr_{0.4}MnO₃(30)/Nd_{0.4}Sr_{0.6}MnO₃(25)/La_{0.2}Sr_{0.8}RuO₃(50)/La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15)

Sample 5-3:

SrTiO₃(100) substrate/La_{0.7}Sr_{0.3}MnO₃(80)/LaAlO₃(1.5)/SrTiO₃(50)/LaAlO₃(1.5)/Nd_{0.6}Sr_{0.4}MnO₃(30)/Nd_{0.4}Sr_{0.6}MnO₃(25)/La_{0.8}Ca_{0.2}VO₃(50)/La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15)

Sample 5-4:

SrTiO₃(100) substrate/La_{0.7}Sr_{0.3}MnO₃(80)/LaAlO₃(1.5)/SrTiO₃(50)/LaAlO₃(1.5)/Nd_{0.6}Sr_{0.4}MnO₃(30)/Nd_{0.4}Sr_{0.6}MnO₃(25)/Pr_{0.7}Ca_{0.3}MnO₃(50)/La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15)

Sample 5-5:

SrTiO₃(100) substrate/La_{0.7}Sr_{0.3}MnO₃(80)/LaAlO₃(1.5)/SrTiO₃(50)/LaAlO₃(1.5)/Nd_{0.6}Sr_{0.4}nO₃(30)/Nd_{0.4}Sr_{0.6}MnO₃(25)/La_{0.7}Ca_{0.3}CrO₃(50)/La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15)

Sample 5-6:

SrTiO₃(100) substrate/La_{0.7}Sr_{0.3}MnO₃(80)/LaAlO₃(1.5)/SrTiO₃(50)/LaAlO₃(1.5)/Nd_{0.6}Sr_{0.4}MnO₃(30)/Nd_{0.4}Sr_{0.6}MnO₃(25)/Gd_{0.9}Ba_{0.1}FeO₃(50)/La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15)

Sample 5-7:

SrTiO₃(100) substrate/La_{0.7}Sr_{0.3}MnO₃(80)/LaAlO₃(1.5)/SrTiO₃(50)/LaAlO₃(1.5)/Nd_{0.6}Sr_{0.4}MnO₃(30)/Nd_{0.4}Sr_{0.6}MnO₃(25)/La_{0.9}Sr_{0.1}NiO₃(50)/La0.7Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15)

Each layer was formed by a PLD method at a substrate temperature of about 600 to 850° C., and each layer of NiFe, Cu, CoFe, Ru and IrMn was manufactured by sputtering at a substrate temperature of a room temperature. The film formation and the conveyance between the respective film formation steps were conducted in an in-situ manner.

Processing was conducted on the laminated bodies by an electron beam (EB) technique and a photolithography technique, which were in conformance with FIGS. 20A-I, to manufacture the configuration in conformance with FIG. 19. Herein, the LaSrMnO₃ layer was provided as an electrode, the LaAlO₃/SrTiO₃/LaAlO₃ layer was provided as an insulation layer, the Nd_{0.6}Sr_{0.4}MnO₃ layer was provided as an antiferromagnetic layer, the Nd_{0.4}Sr_{0.6}MnO₃ layer was provided as a ferromagnetic layer, the Ni_{0.81}Fe_{0.19}/Co_{0.5}Fe_{0.5} layer was provided as a free magnetic layer, the Al₂O₃ layer was provided as a non-magnetic layer, and the Co_{0.5}Fe_{0.5}/Ru/Co_{0.5}Fe_{0.5}/IrMn layer was provided a fixed magnetic layer.

Herein, the magnetic multilayer film of Ni_{0.81}Fe_{0.19}(20)/Co_{0.5}Fe_{0.5}(1)/Al₂O₃(1.2)/Co_{0.5}Fe_{0.5}(5)/Ru(0.9)/Co_{0.5}Fe_{0.5}(5)/IrMn(15) formed a magnetoresistive changing part having a TMR type configuration.

As the transition layer, Sample 5-1 used the La_{0.8}Sr_{0.2}CoO₃ layer, Sample 5-2 used the La_{0.2}Sr_{0.8}RuO₃ layer, Sample 5-3 used the La_{0.8}Ca_{0.2}VO₃ layer, Sample 5-4 used the Pr_{0.7}Ca_{0.3}MnO₃ layer, Sample 5-5 used the La_{0.7}Ca_{0.3}CrO₃ layer, Sample 5-6 used the Gd_{0.9}Ba_{0.1}FeO₃ layer, and Sample 5-7 used the La_{0.9}Sr_{0.1}NiO₃ layer.

Al₂O₃ as the non-magnetic insulation layer was manufactured by forming an Al film, which was subjected to oxidation, followed by post-oxidation process. During this step, multi-stages of Al (0.4 nm) film formation, natural oxidation, Al (0.3 nm) film formation, natural oxidation, Al (0.3 nm) film formation and natural oxidation was conducted. Al₂O₃ after the oxidation had a film thickness of 1.5 nm.

When a voltage 0.1 V≦V≦20 V was applied between the S-W terminals, about at least 20% of difference in resistance could be detected between the B-S terminals of all samples, which showed the formation of desired devices.

### Working Example 6

Samples were manufactured in the following manner using a pulse laser deposition (PLD) technique and a magnetron sputter method.

Sample 6-1

A laminated body was manufactured so as to include NdGaO₃(100) substrate/La_{0.7}Sr_{0.3}MnO₃(80)/LaAlO₃(1.5)/SrTiO₃(50)/LaAlO₃(1.5)/Gd_{0.7}Ca_{0.3}BaMn₂O₆(150)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15) (the unit of numerals in parentheses is nm, which show thicknesses), which was a configuration in conformance with FIG. 22A.

The Gd_{0.7}Ca_{0.3}BaMn₂O₃ layer constituting a transition layer exhibits paramagnetism at a room temperature.

When a voltage was applied between a S terminal and a W terminal, while a pulse current (maximum 10 mA, 1 μs) was applied using an electrode wiring, an external magnetic field was generated effectively so as to enable the operation.

As compared with the case where the pulse current is not applied, the applied voltage could be reduced by about 25%. From this, effective driving could be carried out in terms of a low power consumption operation. Furthermore, since paramagnetism appeared without the application of a voltage, the coupling state of the magnetic layers could be controlled, and a portion of a free magnetic layer could be made independent, which showed that the configuration was suitable for the memory operation.

### Working Example 7

Samples were manufactured in the following manner using a pulse laser deposition (PLD) technique and a magnetron sputter method.

Sample 6-1

A device configuration was formed in conformance with FIGS. 20A-I, including SrTiO₃(100) substrate/SrRuO₃(100)/La_{0.7}Sr_{0.3}MnO₃(80)/Gd_{0.7}Ca_{0.3}BaMn₂O₆(100) /La_{0.7}Sr_{0.3}MnO₃(1.2)/Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15) (the unit of numerals in parentheses is nm, which show thicknesses).

Each layer was formed by a PLD method at a substrate temperature of about 600 to 850° C., and each layer of NiFe, Cu, CoFe, Ru and IrMn was manufactured by sputtering at a substrate temperature of a room temperature (27° C.). The film formation and the conveyance between the respective film formation steps were conducted in an in-situ manner.

Processing was conducted on the laminated body by an electron beam (EB) technique and a photolithography technique, which were in conformance with FIGS. 20A-I. Herein, the SrRuO₃ layer was provided as an electrode, the LaSrMnO layer was provided as a ferromagnetic layer, the GdCaBaMnO layer was provided as a transition layer, the La_{0.7}Sr_{0.3}MnO₃/Ni_{0.81}Fe_{0.19}/Co_{0.5}Fe_{0.5} layer was provided as a free magnetic layer, the Al₂O₃ layer was provided as a non-magnetic layer, and the Co_{0.5}Fe_{0.5}/Ru/Co_{0.5}Fe_{0.5}/IrMn layer was provided a fixed magnetic layer.

Herein, the magnetic multilayer film of Ni_{0.81}Fe_{0.19}(20)/Co_{0.5}Fe_{0.5}(1)/Al₂O₃(1.5)/Co_{0.5}Fe_{0.5}(9)/Ru(0.9)/Co_{0.5}Fe_{0.5}(9)/IrMn(15) formed a magnetoresistive changing part having a TMR type configuration.

Al₂O₃ as the non-magnetic insulation layer was manufactured by forming an Al film, which was subjected to oxidation, followed by post-oxidation processing. During this step, multi-stages of Al (0.4 nm) film formation, natural oxidation, Al (0.3 nm) film formation, natural oxidation, Al (0.3 nm) film formation and natural oxidation was conducted. Al₂O₃ after the oxidation had a film thickness of 1.5 nm.

When a voltage 0.1 V≦V≦20 V was applied between S-W terminals, about at least 20% of difference in resistance could be detected between the B-S terminals of all samples, which showed the formation of desired devices.

### Working Example 8

An integrated memory was manufactured with memory devices having a basic configuration as shown in FIG. 11, where Sample 3-2 indicated in Working Example 3 was used as the elementary device. The devices were arranged so as to constitute eight blocks in total, in which memory including 16×16 devices was set as one block.

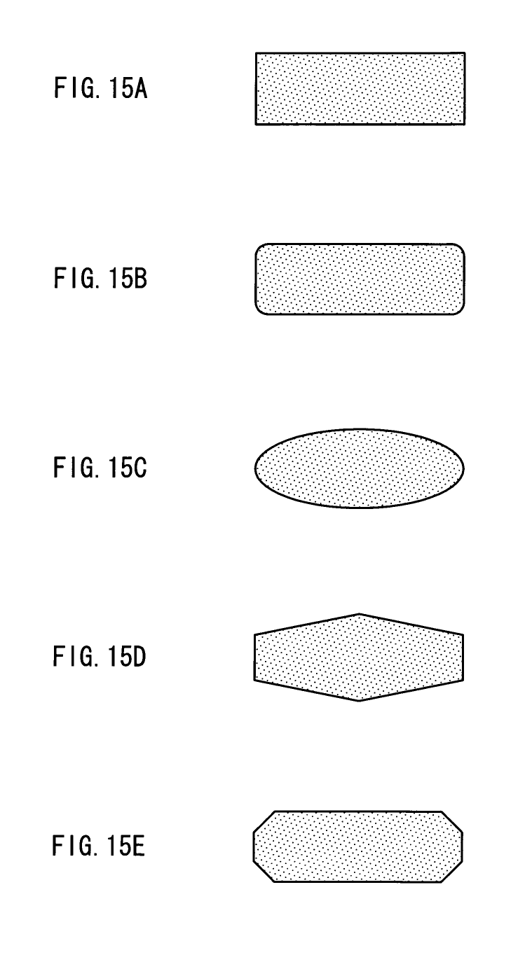

The sample included a device having a cross-sectional area of 0.2 μm×0.3 μm, and had the shape of FIG. 15A.

Word lines and bit lines were all made of Cu.

By the application of a voltage using the word lines and the bit lines and by the application of a magnetic field using the word lines, writing was performed concurrently in eight devices in eight blocks in accordance with information through the magnetization reversal of the respective free magnetic layers, and a 8-bit signal was recorded for each writing operation. Next, a gate of a CMOS that was formed as a pass transistor was turned ON for one device per each block, and a sense current was allowed to flow between P-F, i.e., between a sense line and a bit line. During this step, voltages occurred at bit lines, devices and field effect transistors (FETs) in each block were compared with dummy voltages by a comparator, and 8-bit information was read out concurrently from the output voltage of each device.

Integrated memories were manufactured, in which a ratio between a long axis and a short axis of the free magnetic layer was set at 1.5:1 (short axis: 0.2 μm) and the shape was changed as in FIGS. 15A to E. The memories having the shape of FIGS. 15B to E required power consumption for recording of the memories that was about ⅗ to ½ of that required by the shape of FIG. 15A.

### Working Example 9

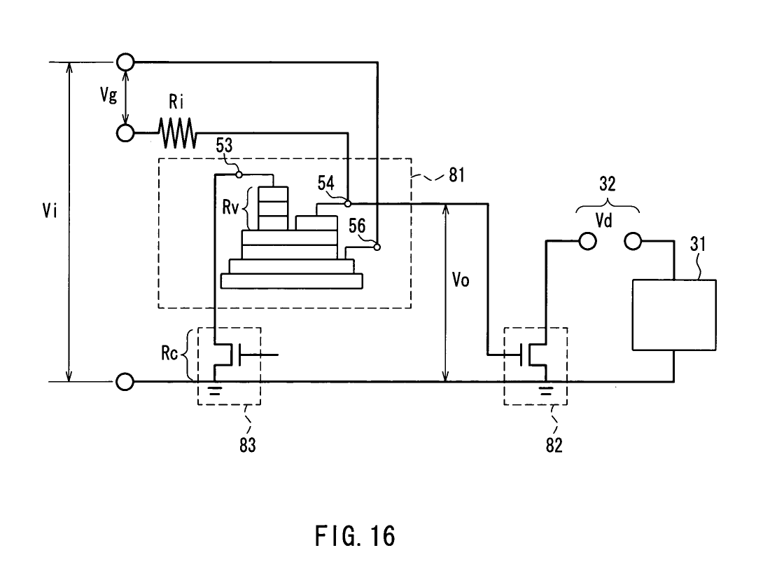

FIG. 16 shows an exemplary configuration of a reconfigurable memory device using a device 81 of one embodiment of the present invention that is configured on a substrate provided with a FET transistor. Assuming that a resistance of a magnetoresistive device portion shown in FIG. 16 is represented by Rv, a voltage V0 applied across a gate portion of a field effect transistor FET1 (82) can be represented using a load resistor Ri and an ON resistance of a field effect transistor FET2 (83) as follows:
V0=[Vi×(Rv+Rc)]/(Ri+Rv+Rc)

Since the magnetoresistive device portion has different resistances of Rvp and Rvap depending on parallel and antiparallel states of the magnetization direction of magnetic layers, the magnitude of V0 varies in accordance with the change in resistance of the magnetoresistive device portion. Herein, it is assumed that Rvp<Rvap. From this, the above formula can be reformulated as follows:
V0p=[Vi×(Rvp+Rc)]/(Ri+Rvp+Rc)
V0ap=[Vi×(Rvap+Rc)]/(Ri+Rvap+Rc)

Thereby, the relationship V0p<V0ap can be obtained.

When the threshold voltage V of the gate portion of the field effect transistor FET1 (82) is set within the range of V0p<V<V0ap, the operation of the field effect transistor FET1 can be controlled in accordance with the memory of the magnetoresistive device portion.

For example, in the case of using a logical circuit as a load circuit 31, this device can be used as a non-volatile programmable device. Furthermore, in the case of using the load circuit as a display circuit device, this device can be used as a non-volatile storage device for a still image. Furthermore, a plurality of these circuits may be integrated to be used as a system LSI. Herein, in FIG. 16, the FET1 (82) and the FET2 (83) can be formed on a wafer, and reference numeral 32 denotes a load voltage of the load circuit.

As described above, according to the present invention, at least one transition layer, at least one electrode and at least one free magnetic layer are included, and at least one of the free magnetic layers is coupled magnetically with the transition layer, and the transition layer undergoes at least magnetic phase change showing ferromagnetism by injecting or inducing electrons or holes, whereby a magnetization direction of the free magnetic layer changes. This configuration is applicable to a magnetic memory that records/reads out magnetization information of the free magnetic layer and various magnetic devices that utilize a resistance change of the magnetoresistive effect portion. Thus, this configuration can enhance the characteristics of a reproduction head of a magnetic recording apparatus used for conventional information communication terminals, such as a magneto-optical disk, a hard disk, a digital data streamer (DDS) and a digital VTR, a cylinder, a magnetic sensor for sensing a rotation speed of a vehicle, a magnetic memory (MRAM), a stress/acceleration sensor that senses a change in stress or acceleration, a thermal sensor, a chemical reaction sensor or the like.

1. A magnetic switching device, comprising:
at least one transition member;
at least one electrode; and
at least one free magnetic member,
wherein the transition member comprises a perovskite compound that contains at least a rare earth element and an alkaline-earth metal,
the electrode and the free magnetic member are arranged in parallel and in a noncontact manner on the transition member,
at least one of the free magnetic members is coupled magnetically with the transition member, and
the transition member undergoes at least ferromagnetism-antiferromagnetism transition by injecting or inducing electrons or holes, whereby a magnetization direction of at least one of the free magnetic members changes.

2. The magnetic switching device according to claim 1, further comprising at least one magnetization stabilization member,
wherein the transition member and the magnetization stabilization member are coupled magnetically, and
the magnetization stabilization member comprises at least one selected from the group consisting of an antiferromagnetic substance, a laminated ferrimagnetic substance and a high coercive force magnetic substance.

3. The magnetic switching device according to claim 1, further comprising:
at least one magnetic member; and
at least one magnetization stabilization member,
wherein the transition member is arranged between the free magnetic member and the magnetic member so as to be coupled magnetically,
the magnetic member and the magnetization stabilization member are coupled magnetically, and
the magnetization stabilization member comprises at least one selected from the group consisting of an antiferromagnetic substance, a laminated ferrimagnetic substance and a high coercive force magnetic substance.

4. The magnetic switching device according to claim 1, further comprising:
at least one magnetic member; and
at least one non-magnetic member,
wherein the free magnetic member and the transition member are coupled magnetically, and
between the free magnetic member and the magnetic member that are connected via the non-magnetic member, a resistance varies in accordance with a change of a magnetization relative angle.

5. The magnetic switching device according to claim 1, further comprising:
at least one non-magnetic member; and
at least one magnetization stabilization member,
wherein the transition member and the magnetization stabilization member are coupled magnetically,
the magnetization stabilization member comprises at least one selected from the group consisting of an antiferromagnetic substance, a laminated ferrimagnetic substance and a high coercive force magnetic substance, and
between the free magnetic member and the magnetic member that are connected via the non-magnetic member, a resistance varies in accordance with a change of a magnetization relative angle.

6. The magnetic switching device according to claim 1, further comprising:
at least two magnetic members;
at least one non-magnetic member; and
at least one magnetization stabilization member,
wherein the transition member is arranged between the free magnetic member and one of the magnetic members so as to be coupled magnetically,
another magnetic member and the magnetization stabilization member are coupled magnetically,
the magnetization stabilization member comprises at least one selected from the group consisting of an antiferromagnetic substance, a laminated ferrimagnetic substance and a high coercive force magnetic substance, and
between the free magnetic member and the magnetic member that are connected via the non-magnetic member, a resistance varies in accordance with a change of a magnetization relative angle.

7. The magnetic switching device according to claim 1, wherein the transition member exhibits paramagnetism or non-magnetism when electrons or holes are not injected or induced.

8. The magnetic switching device according to claim 1,
wherein the transition member undergoes at least paramagnetism-ferromagnetism transition by injecting or inducing electrons or holes, and by assisting with an external magnetic field during the paramagnetism-ferromagnetism transition, a magnetization direction of the transition layer in a ferromagnetic state changes.

9. The magnetic switching device according to claim 1,
wherein the transition member further is opposed to an electrode via at least an insulation member, and
by application of a voltage at least between the transition member and the electrode, the transition member undergoes magnetic transition.

10. The magnetic switching device according to claim 1, wherein the transition member comprises RE₁₋ₓAEₓMEO₃ (RE is a rare earth metal element including Y; AE is an alkaline-earth metal, M is a transition metal element, and x:0<x≦1).

11. The magnetic switching device according to claim 3, wherein at least one selected from the group consisting of the magnetic member, the free magnetic member and the magnetization stabilization member comprises a strongly correlated electron material.

12. The magnetic switching device according to claim 11, wherein the strongly correlated electron material comprises a perovskite type substance or a perovskite type analogous substance containing at least one element selected from the group consisting of a group 3A, a group 4A, a group 5A, a group 6A, a group 7A, a group 8, a group 1B and a group 2B.

13. The magnetic switching device according to claim 12, wherein the strongly correlated electron material comprises RE-ME-O (RE comprises at least one type selected from rare-earth metal elements including Y and ME comprises at least one type selected from transition metal elements).

14. The magnetic switching device according to claim 12, wherein the strongly correlated electron material comprises RE-AE-ME-O (RE comprises at least one type selected from rare-earth metal elements including Y, AE comprises at least one type selected from alkaline-earth metals and ME comprises at least one type selected from transition metal elements).

15. A random access type memory, comprising:
a plurality of voltage switches;
a plurality of transition members that undergo magnetic transition by voltages applied by the voltage switches;
a plurality of free magnetic members whose magnetization directions are changed by the transition members; and
a plurality of magnetoresistive effect portions that read out the magnetization directions of the free magnetic members,
wherein each voltage switch comprises a semiconductor switch device that is integrated on a semiconductor substrate,
the semiconductor switch device comprises at least one transition member, at least one electrode and at least one free magnetic member,
the transition member comprises a perovskite compound that contains at least a rare earth element and an alkaline-earth metal,
the electrode and the free magnetic member are arranged in parallel and in a noncontact manner on the transition member,
at least one of the free magnetic members is coupled magnetically with the transition member, and
the transition member undergoes at least ferromagnetism-antiferromagnetism transition by injecting or inducing electrons or holes, whereby a magnetization direction of at least one of the free magnetic members changes.

16. The random access type memory according to claim 15, wherein the transition member comprises RE₁₋ₓAEₓMEO₃ (RE is a rare earth metal element including Y; AE is an alkaline-earth metal, M is a transition metal element and x:0<x≦1).
